(19) United States
(12) Patent Application Publication
(10) Pub. No.: US 2026/0020302 A1
(43) Pub. Date: Jan. 15, 2026

(54) SEMICONDUCTOR DEVICE

(71) Applicant: Samsung Electronics Co., Ltd., Suwon-si (KR)

(72) Inventors: Jae Ho Jeon, Suwon-si (KR); Dong Hoon Hwang, Suwon-si (KR)

(21) Appl. No.: 19/032,289

(22) Filed: Jan. 20, 2025

(30) Foreign Application Priority Data
Jul. 15, 2024 (KR) 10-2024-0092817

(51) Int. Cl. H10D 62/13; H10D 30/00; H10D 30/43; H10D 62/10; H10D 64/23

(52) U.S. Cl. CPC H10D 62/151; H10D 30/43; H10D 30/502; H10D 62/121; H10D 64/251

(57) ABSTRACT

A semiconductor device includes a lower interlayer insulating layer, an insulating pattern on an upper surface of the lower interlayer insulating layer, a plurality of bottom nanosheets on the insulating pattern, a nanosheet isolation layer on the plurality of bottom nanosheets, the nanosheet isolation layer including an insulating material, a plurality of upper nanosheets on an upper surface of the nanosheet isolation layer, a gate electrode on the insulating pattern, the gate electrode extending around each of the plurality of bottom nanosheets, the nanosheet isolation layer, and the plurality of upper nanosheets, a first bottom source/drain region on a first side of the gate electrode on the insulating pattern, and a first upper source/drain region on the first side of the gate electrode on the first bottom source/drain region, the first upper source/drain region spaced apart from the first bottom source/drain region.

### CROSS-REFERENCE TO RELATED APPLICATION

This application claims priority from Korean Patent Application No. 10-2024-0092817 filed on Jul. 15, 2024 in the Korean Intellectual Property Office, and all the benefits accruing therefrom under 35 U.S.C. 119, the contents of which in its entirety are herein incorporated by reference.

### BACKGROUND

Various example embodiments relate to a semiconductor device. Specifically, the present disclosure relates to a semiconductor device including a MBCFET™ (Multi-Bridge Channel Field Effect Transistor).

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, they are easy to scale. Additionally, the current control capability may be improved without increasing the gate length of the multi-gate transistor. Furthermore, the SCE (short channel effect), in which the potential of the channel region is influenced by the drain voltage, may be effectively suppressed.

### SUMMARY

The present disclosure may provide a semiconductor device that improves reliability by preventing overgrowth of the bottom source/drain region in a structure where a plurality of upper nanosheets are stacked on a plurality of bottom nanosheets.

The embodiments of the present disclosure are not limited to those mentioned above and another aspect which is not mentioned may be clearly understood by those skilled in the art from the description below.

According to some embodiments of the present disclosure, there is provided a semiconductor device, comprising a lower interlayer insulating layer, an insulating pattern extending in a first direction on an upper surface of the lower interlayer insulating layer, a plurality of bottom nanosheets spaced apart from each other in a third direction on the insulating pattern, the third direction intersects the first direction, a nanosheet isolation layer on the plurality of bottom nanosheets, the nanosheet isolation layer comprising an insulating material, a plurality of upper nanosheets spaced apart from each other in the third direction on an upper surface of the nanosheet isolation layer, a gate electrode extending in a second direction different from the first direction on the insulating pattern, the gate electrode extending around each of the plurality of bottom nanosheets, the nanosheet isolation layer, and the plurality of upper nanosheets, a first bottom source/drain region on a first side of the gate electrode on the insulating pattern, and a first upper source/drain region on the first side of the gate electrode and on the first bottom source/drain region, the first upper source/drain region spaced apart from the first bottom source/drain region in the third direction, wherein a first width of the gate electrode in the first direction between an upper surface of an uppermost nanosheet of the plurality of bottom nanosheets and a bottom surface of the nanosheet isolation layer is less than a second width of the gate electrode in the first direction between adjacent ones of the plurality of bottom nanosheets.

According to some embodiments of the present disclosure, there is provided a semiconductor device, comprising a lower interlayer insulating layer, an insulating pattern extending in a first direction on an upper surface of the lower interlayer insulating layer, a plurality of bottom nanosheets spaced apart from each other in a third direction on the insulating pattern, where the third direction intersects the first direction, a nanosheet isolation layer on the plurality of bottom nanosheets, the nanosheet isolation layer comprising an insulating material, a plurality of upper nanosheets spaced apart from each other in the third direction on an upper surface of the nanosheet isolation layer, a gate electrode extending in a second direction different from the first direction on the insulating pattern, the gate electrode extending around each of the plurality of bottom nanosheets, the nanosheet isolation layer, and the plurality of upper nanosheets, a first bottom source/drain region on a first side of the gate electrode on the insulating pattern, and a second bottom source/drain region on a second side of the gate electrode opposite to the first side of the gate electrode in the first direction on the insulating pattern, wherein a first distance in the first direction between the first and second bottom source/drain regions between an upper surface of the uppermost nanosheet of the plurality of bottom nanosheets and a bottom surface of the nanosheet isolation layer is less than a second distance in the first direction between the first and second bottom source/drain regions between adjacent ones of the plurality of bottom nanosheets.

According to some embodiments of the present disclosure, there is provided a semiconductor device, comprising a lower interlayer insulating layer, an insulating pattern extending in a first direction on an upper surface of the lower interlayer insulating layer, a plurality of bottom nanosheets spaced apart from each other in a third direction on the insulating pattern, a nanosheet isolation layer on the plurality of bottom nanosheets, the nanosheet isolation layer comprising an insulating material, a plurality of upper nanosheets spaced apart from each other in the third direction on an upper surface of the nanosheet isolation layer, a gate electrode extending in a second direction different from the first direction on the insulating pattern, the gate electrode extending around each of the plurality of bottom nanosheets, the nanosheet isolation layer, and the plurality of upper nanosheets, a bottom source/drain region on a first side of the gate electrode on the insulating pattern, an upper source/drain region on the first side of the gate electrode on the bottom source/drain region, the upper source/drain region spaced apart from the bottom source/drain region in the third direction, an etching stop layer that is in contact with a sidewall of the nanosheet isolation layer in the first direction, a sidewall in the second direction and an upper surface of the bottom source/drain region, and an upper interlayer insulating layer on the sidewall in the second direction and the upper surface of the bottom source/drain region on the etching stop layer, the upper interlayer insulating layer is in contact with the etching stop layer, wherein each of at least a portion of the etching stop layer and at least a portion of the upper interlayer insulating layer is between an upper surface of the uppermost nanosheet of the plurality of bottom nanosheets and a bottom surface of the nanosheet isolation layer, wherein a first width of the gate electrode in the first direction between the upper surface of the uppermost nanosheet of the plurality of bottom nanosheets and the bottom surface of the nanosheet isolation layer is less than a second width of the gate electrode in the first direction between ones of the plurality of bottom nanosheets, and wherein the first width of the gate electrode in the first direction is less than a third width of the gate electrode in the first direction between the upper surface of the nanosheet isolation layer and a bottom surface of the lowermost nanosheet of the plurality of upper nanosheets.

### BRIEF DESCRIPTION OF THE DRAWINGS

The above and other embodiments and features of the present disclosure will become more apparent by describing in detail example embodiments thereof with reference to the attached drawings, in which:

FIG. 1 is a layout diagram for explaining a semiconductor device according to some embodiments of the present disclosure;

FIG. 2 is a cross-sectional view taken along line A-A′ of FIG. 1;

FIG. 3 is an enlarged view of region R1 of FIG. 2;

FIG. 4 is a cross-sectional view taken along the line B-B′ of FIG. 1;

FIG. 5 is a cross-sectional view taken along the line C-C′ of FIG. 1;

FIGS. 6 to 39 are intermediate stage diagrams for explaining the fabrication methods of semiconductor devices according to some embodiments of the present disclosure;

FIG. 40 is a cross-sectional view for explaining a semiconductor device according to some other embodiments of the present disclosure;

FIG. 41 is a cross-sectional view for explaining a semiconductor device according to another several embodiments of the present disclosure;

FIG. 42 is an enlarged view of the region R2 of FIG. 41;

FIG. 43 is a cross-sectional view for explaining a semiconductor device according to another several embodiments of the present disclosure;

FIG. 44 is an enlarged view of the region R3 of FIG. 43; and

FIGS. 45 and 46 are cross-sectional views for explaining semiconductor devices according to some other embodiments of the present disclosure.

### DETAILED DESCRIPTION OF THE EMBODIMENTS

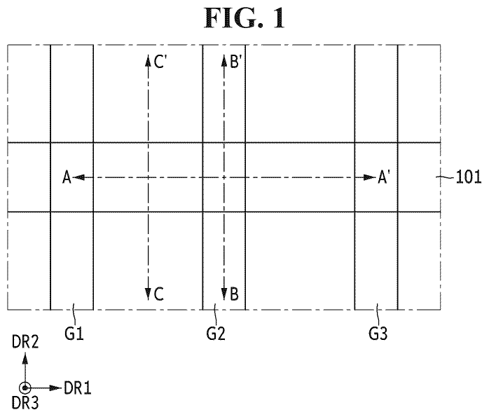

Hereinafter, various example embodiments will be described with reference to FIGS. 1 to 5.

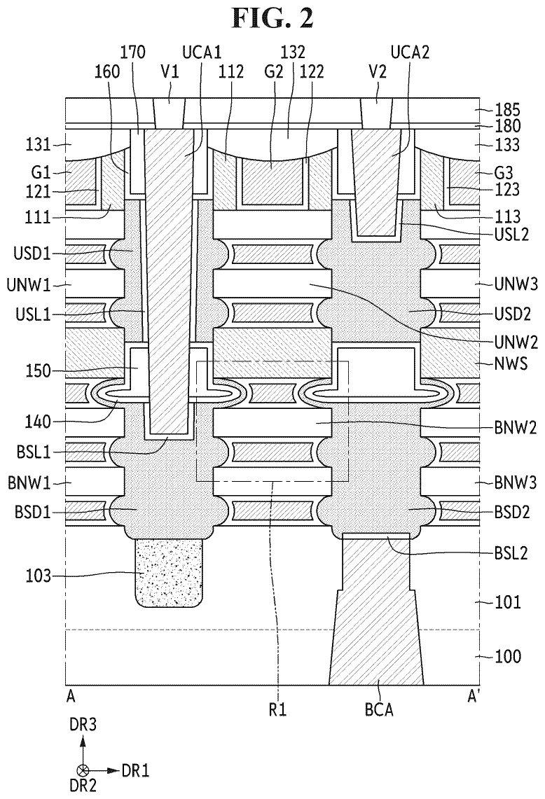

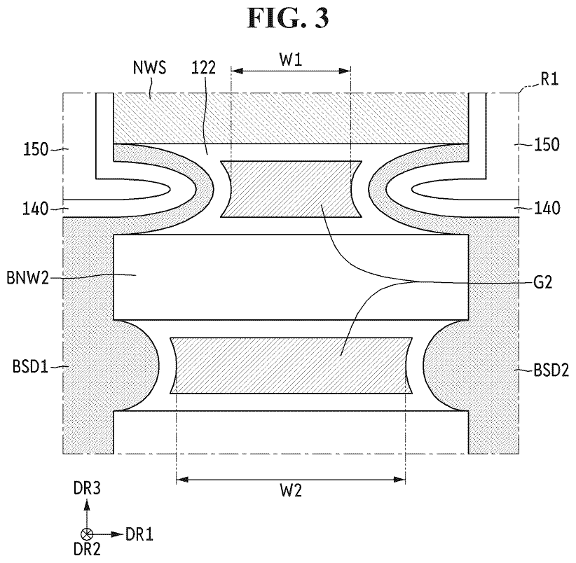

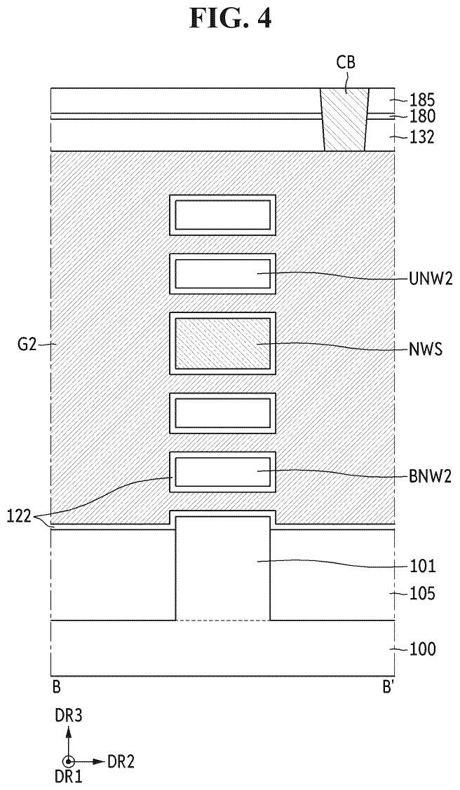

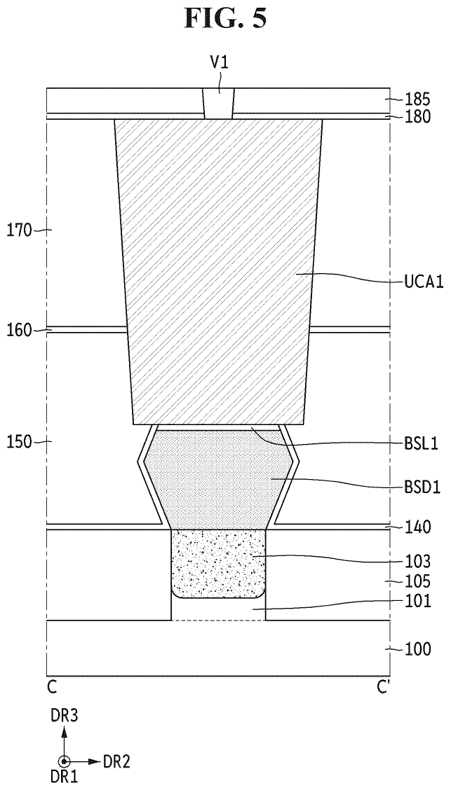

FIG. 1 is a layout diagram for explaining a semiconductor device according to some embodiments of the present disclosure. FIG. 2 is a cross-sectional view taken along line A-A′ of FIG. 1. FIG. 3 is an enlarged view of region R1 of FIG. 2. FIG. 4 is a cross-sectional view taken along the line B-B′ of FIG. 1. FIG. 5 is a cross-sectional view taken along the line C-C′ of FIG. 1.

Referring to FIGS. 1 to 5, a semiconductor device according to some example embodiments of the present disclosure includes a lower interlayer insulating layer 100, an insulating pattern 101, a first sacrificial pattern 103, a field insulating layer 105, first, second, and third plurality of bottom nanosheets BNW1, BNW2, BNW3, a nanosheet isolation layer NWS, first and third plurality of upper nanosheets UNW1, UNW2, UNW3, first, second, and third gate electrodes G1, G2, G3, first, second, and third gate spacers 111, 112, 113, first, second, and third gate insulating layers 121, 122, 123, first, second, and third capping patterns 131, 132, 133, first and second bottom source/drain regions BSD1, BSD2, first and second upper source/drain regions USD1, USD2, a first etching stop layer 140, a first upper interlayer insulating layer 150, first and second upper source/drain contacts UCA1, UCA2, a bottom source/drain contact BCA, first and second bottom silicide layers BSL1, BSL2, first and second upper silicide layers USL1, USL2, a second etching stop layer 160, a second upper interlayer insulating layer 170, a third etching stop layer 180, a third upper interlayer insulating layer 185, a gate contact CB, and first and second vias V1, V2.

The lower interlayer insulating layer 100 may include, for example, at least one of silicon oxide, silicon nitride, silicon oxynitride, and a low-k dielectric material. The low-k dielectric material may include, For example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, but the present disclosure is not limited thereto.

Hereinafter, each of a first horizontal direction DR1 (also referred to herein as the “first direction”) and a second horizontal direction DR2 (also referred to herein as the “second direction”) may be defined as a direction parallel to an upper surface of the lower interlayer insulating layer 100. The second horizontal direction DR2 may be defined as a direction different from the first horizontal direction DR1. A vertical direction DR3 (also referred to herein as the “third direction”) may be defined as a direction perpendicular to each of the first horizontal direction DR1 and the second horizontal direction DR2. In other words, the vertical direction DR3 may be defined as the direction perpendicular to the upper surface of the lower interlayer insulating layer 100.

The insulating pattern 101 may extend in the first horizontal direction DR1 on the upper surface of the lower interlayer insulating layer 100. The insulating pattern 101 may protrude in the vertical direction DR3 from the upper surface of the lower interlayer insulating layer 100. The insulating pattern 101 may include an insulating material. For example, the insulating pattern 101 may include the same material as the lower interlayer insulating layer 100. The field insulating layer 105 may be disposed on the upper surface of the lower interlayer insulating layer 100. The field insulating layer 105 may surround or extend around the sidewall of the insulating pattern 101. For example, the upper surface of the insulating pattern 101 may be formed higher than the upper surface of the field insulating layer 105. That is, at least a portion of the insulating pattern 101 may protrude higher than the upper surface of the field insulating layer 105 in the vertical direction DR3. However, the present disclosure is not limited thereto. In some other example embodiments, the upper surface of the insulating pattern 101 may be formed on the same plane as the upper surface of the field insulating layer 105. The field insulating layer 105 may include, for example, an oxide layer, a nitride layer, an oxynitride layer, or a combination thereof.

Each of the first, second, and third plurality of bottom nanosheets BNW1, BNW2, BNW3 may be disposed on the upper surface of the insulating pattern 101. The second plurality of bottom nanosheets BNW2 may be spaced apart from the first plurality of bottom nanosheets BNW1 in the first horizontal direction DR1. The third plurality of bottom nanosheets BNW3 may be spaced apart from the second plurality of bottom nanosheets BNW2 in the first horizontal direction DR1. Each of the first, second, and third plurality of bottom nanosheets BNW1, BNW2, BNW3 may include a plurality of nanosheets stacked and spaced apart from each other in the vertical direction DR3. In FIG. 2, each of the first, second, and third plurality of bottom nanosheets BNW1, BNW2, BNW3 is illustrated as including two nanosheets stacked and spaced apart from each other in the vertical direction DR3, but the present disclosure is not limited thereto. In some other example embodiments, each of the first, second, and third plurality of bottom nanosheets BNW1, BNW2, BNW3 may include three or more nanosheets stacked and spaced apart from each other in the vertical direction DR3. For example, each of the first, second, and third plurality of bottom nanosheets BNW1, BNW2, BNW3 may include silicon (Si).

The nanosheet isolation layer NWS may be disposed on each of the first, second, and third plurality of bottom nanosheets BNW1, BNW2, BNW3. For example, the nanosheet isolation layer NWS may be spaced apart from the upper surface of the uppermost nanosheets of each of the first, second, and third plurality of bottom nanosheets BNW1, BNW2, BNW3 in the vertical direction DR3. For example, the nanosheet isolation layer NWS disposed on the upper surface of the uppermost nanosheet of the second plurality of bottom nanosheets BNW2 may be spaced apart from the nanosheet isolation layer NWS disposed on the upper surface of the uppermost nanosheet of the first plurality of bottom nanosheets BNW1 in the first horizontal direction DR1. The nanosheet isolation layer NWS disposed on the upper surface of the uppermost nanosheet of the third plurality of bottom nanosheets BNW3 may be spaced apart from the nanosheet isolation layer NWS disposed on the upper surface of the uppermost nanosheet of the second plurality of bottom nanosheets BNW2 in the first horizontal direction DR1.

For example, both sidewalls of the nanosheet isolation layer NWS in the first horizontal direction DR1 may be aligned with both sidewalls of the first horizontal direction DR1 of each of the first, second, and third plurality of bottom nanosheets BNW1, BNW2, BNW3 in the vertical direction DR3. For example, both sidewalls of the nanosheet isolation layer NWS in the second horizontal direction DR2 may be aligned with both sidewalls of the second horizontal direction DR2 of each of the first, second, and third plurality of bottom nanosheets BNW1, BNW2, BNW3 in the vertical direction DR3. The nanosheet isolation layer NWS may include an insulating material. For example, the nanosheet isolation layer NWS may include at least one of silicon nitride (SiN), silicon oxycarbonitride (SiOCN), silicon boron carbonitride (SiBCN), silicon carbonitride (SiCN), silicon oxynitride (SiON), and/or combinations thereof. However, the present disclosure is not limited thereto.

Each of the first, second, and third plurality of upper nanosheets UNW1, UNW2, UNW3 may be disposed on the upper surface of the nanosheet isolation layer NWS. The second plurality of upper nanosheets UNW2 may be spaced apart from the first plurality of upper nanosheets UNW1 in the first horizontal direction DR1. The third plurality of upper nanosheets UNW3 may be spaced apart from the second plurality of upper nanosheets UNW2 in the first horizontal direction DR1. Each of the first, second, and third plurality of upper nanosheets UNW1, UNW2, UNW3 may include a plurality of nanosheets stacked and spaced apart from each other in the vertical direction DR3. In FIG. 2, each of the first, second, and third plurality of upper nanosheets UNW1, UNW2, UNW3 is illustrated as including two nanosheets stacked and spaced apart from each other in the vertical direction DR3, but the present disclosure is not limited thereto. In some other example embodiments, each of the first, second, and third plurality of upper nanosheets UNW1, UNW2, UNW3 may include three or more nanosheets stacked and spaced apart from each other in the vertical direction DR3. For example, each of the first, second, and third plurality of upper nanosheets UNW1, UNW2, UNW3 may include silicon (Si).

Each of the first, second, and third gate electrodes G1, G2, G3 may extend in the second horizontal direction DR2 on the insulating pattern 101 and the field insulating layer 105. The second gate electrode G2 may be spaced apart from the first gate electrode G1 in the first horizontal direction DR1. The third gate electrode G3 may be spaced apart from the second gate electrode G2 in the first horizontal direction DR1. The first gate electrode G1 may surround or extend around each of the first plurality of bottom nanosheets BNW1, the nanosheet isolation layer NWS, and the first plurality of upper nanosheets UNW1. The second gate electrode G2 may surround each of the second plurality of bottom nanosheets BNW2, the nanosheet isolation layer NWS, and the second plurality of upper nanosheets UNW2. The third gate electrode G3 may surround each of the third plurality of bottom nanosheets BNW3, the nanosheet isolation layer NWS, and the third plurality of upper nanosheets UNW3.

For example, the first width W1 of the second gate electrode G2 in the first horizontal direction DR1 between the upper surface of the uppermost nanosheet of the second plurality of bottom nanosheets BNW2 and the bottom surface of the nanosheet isolation layer NWS is smaller than or less than the second width W2 of the second gate electrode G2 in the first horizontal direction DR1 between adjacent the second plurality of bottom nanosheets BNW2. For example, the first width W1 of the second gate electrode G2 in the first horizontal direction DR1 between the upper surface of the uppermost nanosheet of the second plurality of bottom nanosheets BNW2 and the bottom surface of the nanosheet isolation layer NWS is smaller than or less than the third width W3 between the upper surface of the nanosheet isolation layer NWS and the bottom surface of the lowermost nanosheet of the second plurality of upper nanosheets UNW2.

For example, each of the first, second, and third gate electrodes G1, G2, G3 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof. Each of the first, second, and third gate electrodes G1, G2, G3 may include a conductive metal oxide, a conductive metal oxynitride, etc., and/or may also include the oxidized form of the aforementioned materials.

The first gate spacer 111 may extend in the second horizontal direction DR2 along both sidewalls of the first gate electrode G1 on the upper surface of the uppermost nanosheet of the first plurality of upper nanosheets UNW1 and the upper surface of the field insulating layer 105. The second gate spacer 112 may extend in the second horizontal direction DR2 along both sidewalls of the second gate electrode G2 on the upper surface of the uppermost nanosheet of the second plurality of upper nanosheets UNW2 and the upper surface of the field insulating layer 105. The third gate spacer 113 may extend in the second horizontal direction DR2 along both sidewalls of the third gate electrode G3 on the upper surface of the uppermost nanosheet of the third plurality of upper nanosheets UNW3 and the upper surface of the field insulating layer 105. For example, each of the first, second, and third gate spacers 111, 112, 113 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and/or combinations thereof. However, the present disclosure is not limited thereto.

The first bottom source/drain region BSD1 may be disposed on a first side of the second gate electrode G2 on the insulating pattern 101. For example, the first bottom source/drain region BSD1 may be disposed between the first gate electrode G1 and the second gate electrode G2 on the insulating pattern 101. The first bottom source/drain region BSD1 may be in contact with the sidewall of each of the first and second plurality of bottom nanosheets BNW1, BNW2 in the first horizontal direction DR1. The second bottom source/drain region BSD2 may be disposed on a second side of the second gate electrode G2 opposite the first side of the second gate electrode G2 in the first horizontal direction DR1 on the insulating pattern 101. For example, the second bottom source/drain region BSD2 may be disposed between the second gate electrode G2 and the third gate electrode G3 on the insulating pattern 101. The second bottom source/drain region BSD2 may be in contact with the sidewall of each of the second and third plurality of bottom nanosheets BNW2, BNW3 in the first horizontal direction DR1.

For example, at least a portion of the first bottom source/drain region BSD1 may be disposed between the uppermost surface of the insulating pattern 101 and the bottom surface of the lowermost nanosheet of each of the first and second plurality of bottom nanosheets BNW1, BNW2. At least a portion of the second bottom source/drain region BSD2 may be disposed between the uppermost surface of the insulating pattern 101 and the bottom surface of the lowermost nanosheet of each of the second and third plurality of bottom nanosheets BNW2, BNW3. For instance, at least a portion of the first bottom source/drain region BSD1 may be disposed between adjacent the first plurality of bottom nanosheets BNW1. At least a portion of the first bottom source/drain region BSD1 may be disposed between adjacent the second plurality of bottom nanosheets BNW2. At least a portion of the second bottom source/drain region BSD2 may be disposed between adjacent the second plurality of bottom nanosheets BNW2. At least a portion of the second bottom source/drain region BSD2 may be disposed between adjacent the third plurality of bottom nanosheets BNW3.

For example, at least a portion of the first bottom source/drain region BSD1 may be disposed between the upper surface of the uppermost nanosheet of each of the first and second plurality of bottom nanosheets BNW1, BNW2 and the bottom surface of the nanosheet isolation layer NWS. At least a portion of the second bottom source/drain region BSD2 may be disposed between the upper surface of the uppermost nanosheet of each of the second and third plurality of bottom nanosheets BNW2, BNW3 and the bottom surface of the nanosheet isolation layer NWS. For example, at least a portion of the first bottom source/drain region BSD1 may be in contact with the upper surface of the uppermost nanosheet of each of the first and second plurality of bottom nanosheets BNW1, BNW2. At least a portion of the second bottom source/drain region BSD2 may be in contact with the upper surface of the uppermost nanosheet of each of the second and third plurality of bottom nanosheets BNW2, BNW3. For example, at least a portion of the first bottom source/drain region BSD1 may be in contact with the bottom surface of the nanosheet isolation layer NWS. At least a portion of the second bottom source/drain region BSD2 may be in contact with the bottom surface of the nanosheet isolation layer NWS.

The first upper source/drain region USD1 may be disposed on the first side of the second gate electrode G2 on the first bottom source/drain region BSD1. For example, the first upper source/drain region USD1 may be disposed between the first gate electrode G1 and the second gate electrode G2 on the first bottom source/drain region BSD1. The first upper source/drain region USD1 may be spaced apart from the first bottom source/drain region BSD1 in the vertical direction DR3. The first upper source/drain region USD1 may be in contact with the sidewall of each of the first and second plurality of upper nanosheets UNW1, UNW2 in the first horizontal direction DR1. The second upper source/drain region USD2 may be disposed on the second side of the second gate electrode G2 on the second bottom source/drain region BSD2. For example, the second upper source/drain region USD2 may be disposed between the second gate electrode G2 and the third gate electrode G3 on the second bottom source/drain region BSD2. The second upper source/drain region USD2 may be spaced apart from the second bottom source/drain region BSD2 in the vertical direction DR3. The second upper source/drain region USD2 may be in contact with the sidewall of each of the second and third plurality of upper nanosheets UNW2, UNW3 in the first horizontal direction DR1.

For example, at least a portion of the first upper source/drain region USD1 may be disposed between the upper surface of the nanosheet isolation layer NWS and the bottom surface of the lowermost nanosheet of each of the first and second plurality of upper nanosheets UNW1, UNW2. At least a portion of the second upper source/drain region USD2 may be disposed between the upper surface of the nanosheet isolation layer NWS and the bottom surface of the lowermost nanosheet of each of the second and third plurality of upper nanosheets UNW2, UNW3. For example, at least a portion of the first upper source/drain region USD1 may be disposed between adjacent the first plurality of upper nanosheets UNW1. At least a portion of the first upper source/drain region USD1 may be disposed between adjacent the second plurality of upper nanosheets UNW2. At least a portion of the second upper source/drain region USD2 may be disposed between adjacent the second plurality of upper nanosheets UNW2. At least a portion of the second upper source/drain region USD2 may be disposed between adjacent the third plurality of upper nanosheets UNW3.

For example, the first distance in the first horizontal direction DR1 between the first and second bottom source/drain regions BSD1, BSD2 between the upper surface of the uppermost nanosheet of the second plurality of bottom nanosheets BNW2 and the bottom surface of the nanosheet isolation layer NWS is smaller than or less than the second distance in the first horizontal direction DR1 between the first and second bottom source/drain regions BSD1, BSD2 between adjacent the second plurality of bottom nanosheets BNW2. For example, the first distance in the first horizontal direction DR1 between the first and second bottom source/drain regions BSD1, BSD2 between the upper surface of the uppermost nanosheet of the second plurality of bottom nanosheets UNW2 and the bottom surface of the nanosheet isolation layer NWS is smaller than or less than the third distance in the first horizontal direction DR1 between the first and second upper source/drain regions USD1, USD2 between the upper surface of the nanosheet isolation layer NWS and the bottom surface of the lowermost nanosheet of the second plurality of upper nanosheets UNW2.

In FIG. 2, each of the first and second plurality of bottom nanosheets BNW1, BNW2, each of the first and second plurality of upper nanosheets UNW1, UNW2 is illustrated as being formed as a single layer, but this is for the convenience of explanation only, and the present disclosure is not limited thereto. That is, each of the first and second plurality of bottom nanosheets BNW1, BNW2, each of the first and second plurality of upper nanosheets UNW1, UNW2 may be formed as multiple layers. For example, the second gate electrode G2, the second plurality of bottom nanosheets BNW2, and the first and second bottom source/drain regions BSD1, BSD2 may form a PMOS transistor. For example, the second gate electrode G2, the second plurality of upper nanosheets UNW2, and the first and second upper source/drain regions USD1, USD2 may form an NMOS transistor.

The first sacrificial pattern 103 may be disposed beneath the first bottom source/drain region BSD1. For example, the first sacrificial pattern 103 may be disposed inside the insulating pattern 101. In FIG. 2, it is illustrated that the bottom surface of the first sacrificial pattern 103 is in contact with the insulating pattern 101, but the present disclosure is not limited thereto. In some other example embodiments, the bottom surface of the first sacrificial pattern 103 may be in contact with the lower interlayer insulating layer 100. For example, the first sacrificial pattern 103 may include silicon germanium (SiGe).

The first gate insulating layer 121 may be disposed between the first gate electrode G1 and the insulating pattern 101. The first gate insulating layer 121 may be disposed between the first gate electrode G1 and the first plurality of bottom nanosheets BNW1. The first gate insulating layer 121 may be disposed between the first gate electrode G1 and the nanosheet isolation layer NWS. The first gate insulating layer 121 may be disposed between the first gate electrode G1 and the first plurality of upper nanosheets UNW1. The first gate insulating layer 121 may be disposed between the first gate electrode G1 and the first gate spacer 111. The first gate insulating layer 121 may be disposed between the first gate electrode G1 and the first bottom source/drain region BSD1. The first gate insulating layer 121 may be disposed between the first gate electrode G1 and the first upper source/drain region USD1.

The second gate insulating layer 122 may be disposed between the second gate electrode G2 and the insulating pattern 101. The second gate insulating layer 122 may be disposed between the second gate electrode G2 and the second plurality of bottom nanosheets BNW2. The second gate insulating layer 122 may be disposed between the second gate electrode G2 and the nanosheet isolation layer NWS. The second gate insulating layer 122 may be disposed between the second gate electrode G2 and the second plurality of upper nanosheets UNW2. The second gate insulating layer 122 may be disposed between the second gate electrode G2 and the second gate spacer 112. The second gate insulating layer 122 may be disposed between the second gate electrode G2 and each of the first and second bottom source/drain regions BSD1, BSD2. The second gate insulating layer 122 may be disposed between the second gate electrode G2 and each of the first and second upper source/drain regions USD1, USD2.

The third gate insulating layer 123 may be disposed between the third gate electrode G3 and the insulating pattern 101. The third gate insulating layer 123 may be disposed between the third gate electrode G3 and the third plurality of bottom nanosheets BNW3. The third gate insulating layer 123 may be disposed between the third gate electrode G3 and the nanosheet isolation layer NWS. The third gate insulating layer 123 may be disposed between the third gate electrode G3 and the third plurality of upper nanosheets UNW3. The third gate insulating layer 123 may be disposed between the third gate electrode G3 and the third gate spacer 113. The third gate insulating layer 123 may be disposed between the third gate electrode G3 and the third bottom source/drain region BSD3. The third gate insulating layer 123 may be disposed between the third gate electrode G3 and the third upper source/drain region USD3.

For example, the first gate insulating layer 121 may be in contact with the first bottom source/drain region BSD1, the second gate insulating layer 122 may be in contact with each of the first and second bottom source/drain regions BSD1, BSD2, and the third gate insulating layer 123 may be in contact with the third bottom source/drain region BSD3. For example, the first gate insulating layer 121 may be in contact with the first upper source/drain region USD1, the second gate insulating layer 122 may be in contact with each of the first and second upper source/drain regions USD1, USD2, and the third gate insulating layer 123 may be in contact with the third upper source/drain region USD3. However, the present disclosure is not limited thereto. In some other example embodiments, an inner spacer may be disposed between the first gate insulating layer 121 and the first upper source/drain region USD1, between the second gate insulating layer 122 and the first upper source/drain region USD1, between the second gate insulating layer 122 and the second upper source/drain region USD2, and between the third gate insulating layer 123 and the third upper source/drain region USD3, respectively. For example, the inner spacer may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and/or combinations thereof.

Each of the first, second, and third gate insulating layers 121, 122, 123 may include at least one of silicon oxide, silicon oxynitride, silicon nitride, or a high-k dielectric material with a dielectric constant greater than that of silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some example embodiments may include a NC (Negative Capacitance) FET utilizing a negative capacitor. For example, each of the first, second, and third gate insulating layers 121, 122, 123 may include a ferroelectric material layer with ferroelectric properties and a paraelectric material layer with paraelectric properties.

The ferroelectric material layer may have a negative capacitance, while the paraelectric material layer may have a positive capacitance. For example, when two or more capacitors are connected in series and each of their capacitances has a positive value, the overall capacitance may be less than the capacitance of each individual capacitor. On the other hand, when at least one of the capacitances of the two or more capacitors connected in series has a negative value, the overall capacitance may have a positive value and be greater than the absolute value of each individual capacitance.

When the ferroelectric material layer with a negative capacitance and the paraelectric material layer with a positive capacitance are connected in series, the overall capacitance value of the ferroelectric material layer and the paraelectric material layer connected in series may be increased. By utilizing the increase in overall capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. In another example, hafnium zirconium oxide may be a material in which zirconium (Zr) is doped into hafnium oxide. In another example, hafnium zirconium oxide may be a compound of hafnium (Hf) and zirconium (Zr) with oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). Depending on which ferroelectric material the ferroelectric material layer includes, the type of dopant included in the ferroelectric material layer may vary.

When the ferroelectric material layer includes hafnium oxide, the dopant included in the ferroelectric material layer may include, for example, at least one of gadolinium (Gd), silicon (Si), zirconium (Zr), aluminum (Al), and/or yttrium (Y).

When the dopant is aluminum (Al), the ferroelectric material layer may include 3 to 8 at % (atomic %) of aluminum. Here, the ratio of the dopant may be a ratio of aluminum to the sum of hafnium and aluminum.

When the dopant is silicon (Si), the ferroelectric material layer may include 2 to 10 at % of silicon. When the dopant is yttrium (Y), the ferroelectric material layer may include 2 to 10 at % of yttrium. When the dopant is gadolinium (Gd), the ferroelectric material layer may include 1 to 7 at % of gadolinium. When the dopant is zirconium (Zr), the ferroelectric material layer may include 50 to 80 at % of zirconium.

The paraelectric material layer may have paraelectric properties. The paraelectric material layer may include, for example, at least one of silicon oxide and a high-k metal oxide. The metal oxide included in the paraelectric material layer may include, for example, at least one of hafnium oxide, zirconium oxide, and/or aluminum oxide, but is not limited thereto.

The ferroelectric material layer and the paraelectric material layer may include the same material. While the ferroelectric material layer may have ferroelectric properties, the paraelectric material layer may not have ferroelectric properties. For example, when the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Since the critical thickness exhibiting ferroelectric properties may vary for each ferroelectric material, the thickness of the ferroelectric material layer may vary depending on the ferroelectric material.

As an example, each of the first, second, and third gate insulating layers 121, 122, 123 may include a single ferroelectric material layer. In another example, each of the first, second, and third gate insulating layers 121, 122, 123 may include a plurality of ferroelectric material layers spaced apart from each other. Each of the first, second, and third gate insulating layers 121, 122, 123 may have a stacked layer structure in which the plurality of ferroelectric material layers and the plurality of paraelectric material layers are alternately stacked.

The first etching stop layer 140 may be disposed on the upper surface of each of the first and second bottom source/drain regions BSD1, BSD2 and on the sidewall of the nanosheet isolation layer NWS in the first horizontal direction DR1. The first etching stop layer 140 may be disposed on the sidewall of each of the first and second bottom source/drain regions BSD1, BSD2 in the second horizontal direction DR2 and on the upper surface of the field insulating layer 105. For example, the first etching stop layer 140 may be in contact with the sidewall of the nanosheet isolation layer NWS in the first horizontal direction DR1, the sidewall and the upper surface of each of the first and second bottom source/drain regions BSD1, BSD2 in the second horizontal direction DR2, and the upper surface of the field insulating layer 105, respectively. For example, the first etching stop layer 140 may be formed conformally. For example, at least a portion of the first etching stop layer 140 may be disposed between the upper surface of the uppermost nanosheet of each of the first, second, and third plurality of bottom nanosheets BNW1, BNW2, BNW3 and the bottom surface of the nanosheet isolation layer NWS. For example, the first etching stop layer 140 may include at least one of aluminum oxide, aluminum nitride, hafnium oxide, zirconium oxide, silicon oxide, silicon nitride, silicon oxynitride, and/or a low-k dielectric material.

The first upper interlayer insulating layer 150 may be disposed on the first etching stop layer 140. For example, the first upper interlayer insulating layer 150 may cover, overlap, or be on the sidewall of the nanosheet isolation layer NWS in the first horizontal direction DR1, the sidewall and upper surface of each of the first and second bottom source/drain regions BSD1, BSD2 in the second horizontal direction DR2. The first upper interlayer insulating layer 150 may be in contact with the first etching stop layer 140. For example, the upper surface of the first upper interlayer insulating layer 150 may be formed lower than the upper surface of the nanosheet isolation layer NWS. For example, at least a portion of the first upper interlayer insulating layer 150 may be disposed between the upper surface of the uppermost nanosheet of each of the first, second, and third plurality of bottom nanosheets BNW1, BNW2, BNW3 and the bottom surface of the nanosheet isolation layer NWS. For example, the first upper interlayer insulating layer 150 may include at least one of silicon oxide, silicon nitride, silicon oxynitride, and/or a low-k dielectric material.

The second etching stop layer 160 may be disposed on the upper surface of the first upper interlayer insulating layer 150, on the upper surface of each of the first and second upper source/drain regions USD1, USD2, and on the sidewall of each of the first, second, and third gate spacers 111, 112, 113. For example, the second etching stop layer 160 may be formed conformally. For example, the second etching stop layer 160 may include at least one of aluminum oxide, aluminum nitride, hafnium oxide, zirconium oxide, silicon oxide, silicon nitride, silicon oxynitride, and/or a low-k dielectric material. The second upper interlayer insulating layer 170 may be disposed on the second etching stop layer 160. For example, the second upper interlayer insulating layer 170 may cover each of the first, second, and third gate spacers 111, 112, 113, and each of the first and second upper source/drain regions USD1, USD2. For example, the second upper interlayer insulating layer 170 may include at least one of silicon oxide, silicon nitride, silicon oxynitride, and/or a low-k dielectric material.

The first capping pattern 131 may extend in the second horizontal direction DR2 on each of the first gate spacer 111, the first gate insulating layer 121, and the first gate electrode G1. The second capping pattern 132 may extend in the second horizontal direction DR2 on each of the second gate spacer 112, the second gate insulating layer 122, and the second gate electrode G2. The third capping pattern 133 may extend in the second horizontal direction DR2 on each of the third gate spacer 113, the third gate insulating layer 123, and the third gate electrode G3. For example, the bottom surface of each of the first, second, and third capping patterns 131, 132, 133 may be in contact with the second etching stop layer 160, but the present disclosure is not limited thereto. For example, each of the first, second, and third capping patterns 131, 132, 133 may include at least one of silicon nitride (SiN), silicon oxynitride (SiON), silicon oxide (SiO₂), silicon carbonitride (SiCN), silicon oxycarbonitride (SiOCN), and/or combinations thereof. However, the present disclosure is not limited thereto.

The first upper source/drain contact UCA1 may penetrate or extend into the second upper interlayer insulating layer 170, the second etching stop layer 160, the first upper source/drain region USD1, the first etching stop layer 140, and the first upper interlayer insulating layer 150 in the vertical direction DR3 and extend into the inside of the first bottom source/drain region BSD1. For example, the first upper source/drain contact UCA1 may be electrically connected to each of the first upper source/drain region USD1 and the first bottom source/drain region BSD1. For example, the upper surface of the first upper source/drain contact UCA1 may be formed on the same plane as the upper surface of the second upper interlayer insulating layer 170.

The second upper source/drain contact UCA2 may penetrate or extend into the second upper interlayer insulating layer 170 and the second etching stop layer 160 in the vertical direction DR3 and extend into the inside of the second upper source/drain region USD2. For example, the second upper source/drain contact UCA2 may be electrically connected to the second upper source/drain region USD2. For example, the upper surface of the second upper source/drain contact UCA2 may be formed on the same plane as the upper surface of the second upper interlayer insulating layer 170. The bottom source/drain contact BCA may be disposed under the second bottom source/drain region BSD2. The bottom source/drain contact BCA may penetrate or extend into the lower interlayer insulating layer 100 and insulating pattern 101 in the vertical direction DR3 and extend to the bottom surface of the second bottom source/drain region BSD2. For example, the bottom source/drain contact BCA may be electrically connected to the second bottom source/drain region BSD2.

In FIGS. 2 and 5, each of the first and second upper source/drain contacts UCA1, UCA2 and the bottom source/drain contact BCA is illustrated as being formed as a single layer, but the present disclosure is not limited thereto. In some example embodiments, each of the first and second upper source/drain contacts UCA1, UCA2, and the bottom source/drain contact BCA may be formed as multiple layers. Each of the first and second upper source/drain contacts UCA1, UCA2, and the bottom source/drain contact BCA may include a conductive material.

The first bottom silicide layer BSL1 may be disposed along the interface between the first bottom source/drain region BSD1 and the first upper source/drain contact UCA1. The second bottom silicide layer BSL2 may be disposed along the interface between the second bottom source/drain region BSD2 and the bottom source/drain contact BCA. The first upper silicide layer USL1 may be disposed along the interface between the first upper source/drain region USD1 and the first upper source/drain contact UCA1. The second upper silicide layer USL2 may be disposed along the interface between the second upper source/drain region USD2 and the second upper source/drain contact UCA2. For example, each of the first and second bottom silicide layers BSL1, BSL2 and the first and second upper silicide layers USL1, USL2 may include a metal silicide material.

The third etching stop layer 180 may be disposed on the upper surface of each of the first, second, and third capping patterns 131, 132, 133, the second upper interlayer insulating layer 170, and the first and second upper source/drain contacts UCA1, UCA2. For example, the third etching stop layer 180 may be formed conformally. In FIGS. 2, 4, and 5, the third etching stop layer 180 is illustrated as being formed as a single layer, but the present disclosure is not limited thereto. In some example embodiments, the third etching stop layer 180 may be formed as multiple layers. The third etching stop layer 180 may include, for example, at least one of aluminum oxide, aluminum nitride, hafnium oxide, zirconium oxide, silicon oxide, silicon nitride, silicon oxynitride, and/or a low-k dielectric material. The third upper interlayer insulating layer 185 may be disposed on the third etching stop layer 180. The third upper interlayer insulating layer 185 may include, for example, at least one of silicon oxide, silicon nitride, silicon oxynitride, and/or a low-k dielectric material.

The gate contact CB may penetrate the third upper interlayer insulating layer 185, the third etching stop layer 180, and the second capping pattern 132 in the vertical direction DR3 and be connected to the second gate electrode G2. In FIG. 4, the gate contact CB is illustrated as being formed as a single layer, but the present disclosure is not limited thereto. In some example embodiments, the gate contact CB may be formed as multiple layers. The gate contact CB may include a conductive material. A first via V1 may penetrate or extend into the third upper interlayer insulating layer 185 and the third etching stop layer 180 in the vertical direction DR3 and may be connected to the first upper source/drain contact UCA1. A second via V2 may penetrate or extend into the third upper interlayer insulating layer 185 and the third etching stop layer 180 in the vertical direction DR3 and may be connected to the second upper source/drain contact UCA2. Each of the first and second vias V1, V2 may include a conductive material.

The semiconductor device according to some example embodiments of the present disclosure may include a structure in which the second plurality of bottom nanosheets BNW2, the nanosheet isolation layer NWS, and the second plurality of upper nanosheets UNW2 are sequentially stacked. In the semiconductor device according to some example embodiments of the present disclosure, the first width W1 of the second gate electrode G2 in the first horizontal direction DR1 between the upper surface of the uppermost nanosheet of the second plurality of bottom nanosheets BNW2 and the bottom surface of the nanosheet isolation layer NWS is formed to be smaller than or less than the second width W2 of the second gate electrode G2 in the first horizontal direction DR1 between adjacent the second plurality of bottom nanosheets BNW2. In the semiconductor device according to some example embodiments of the present disclosure, at least a portion of each of the first and second bottom source/drain regions BSD1, BSD2 may be filled on both sidewalls of the second gate electrode G2 in the first horizontal direction DR1 between the upper surface of the uppermost nanosheet of the second plurality of bottom nanosheets BNW2 and the bottom surface of the nanosheet isolation layer NWS. Accordingly, the semiconductor device according to some example embodiments of the present disclosure may prevent each of the first and second bottom source/drain regions BSD1, BSD2 from overgrowing, thereby improving the reliability of the semiconductor device.

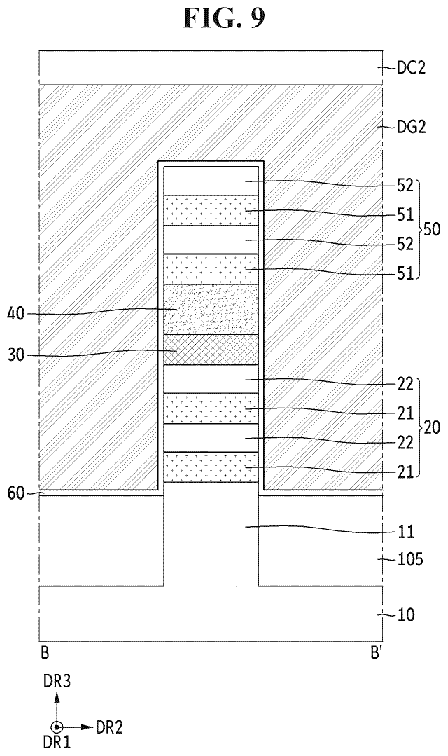

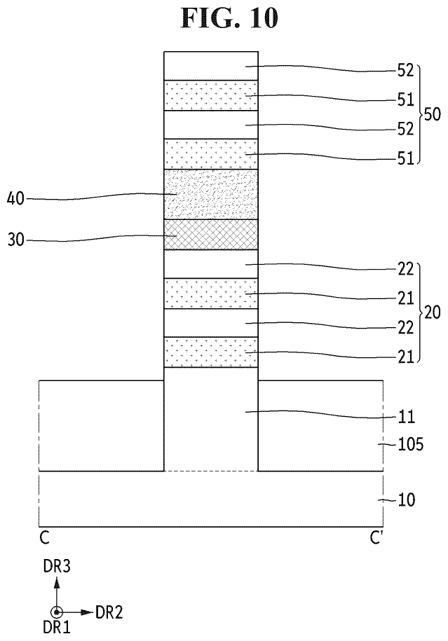

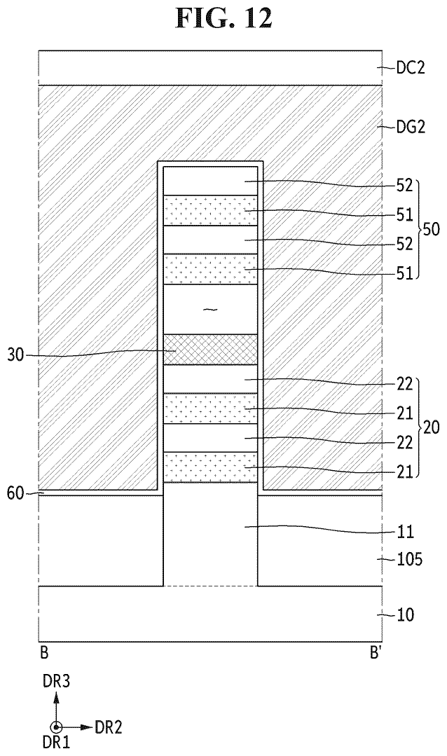

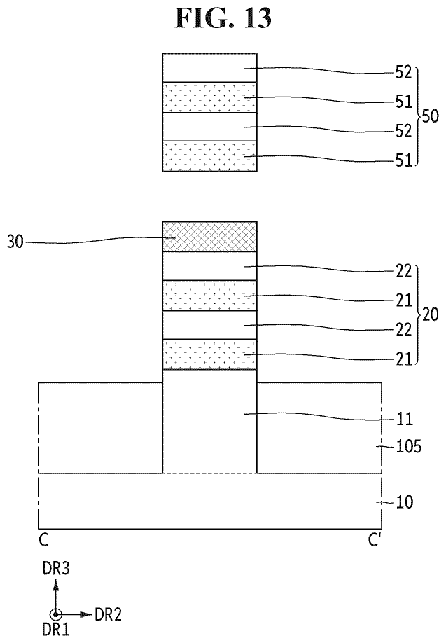

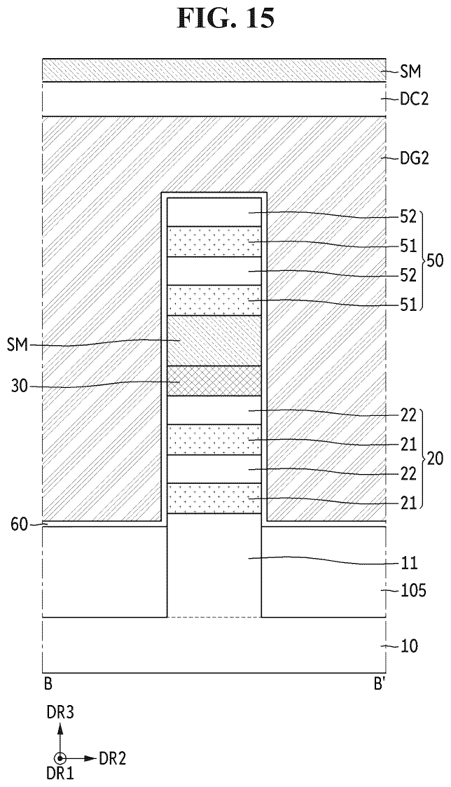

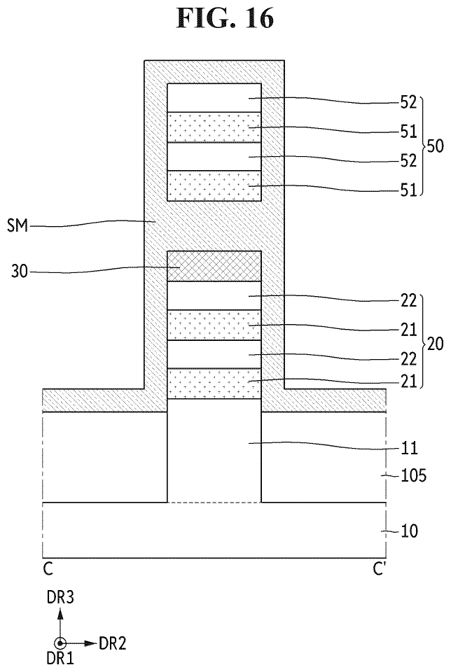

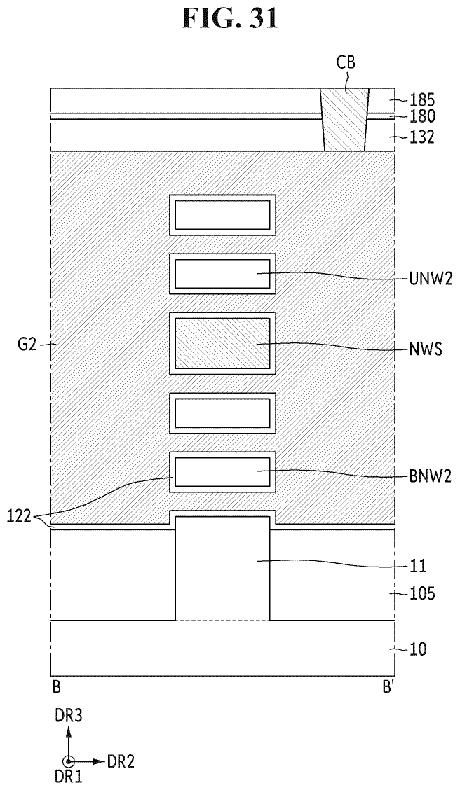

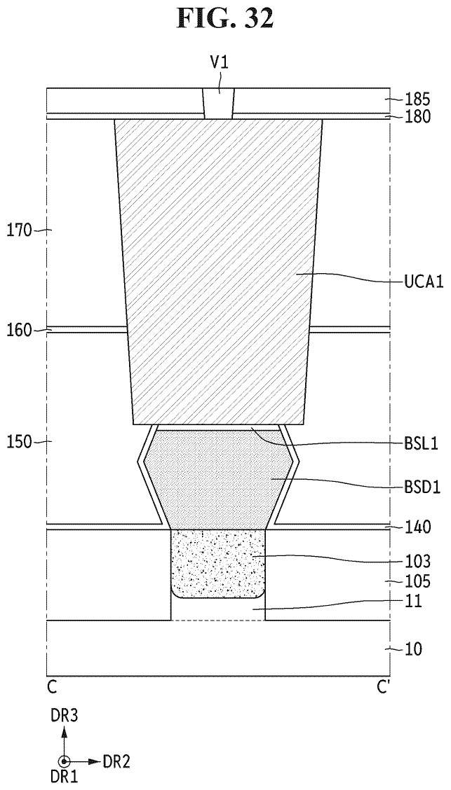

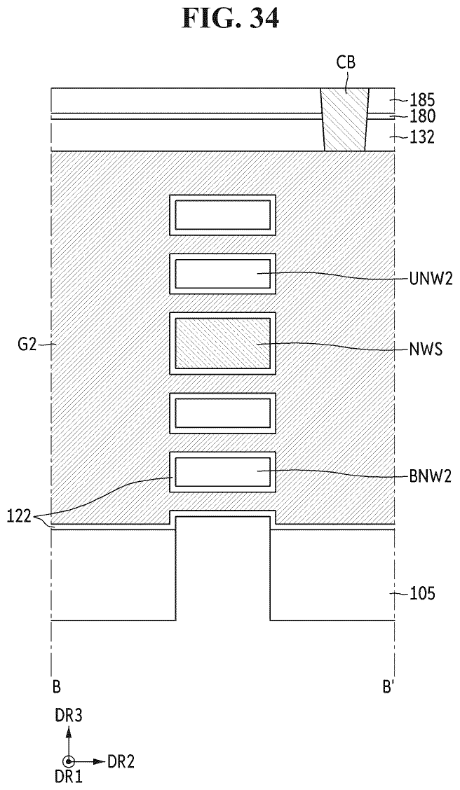

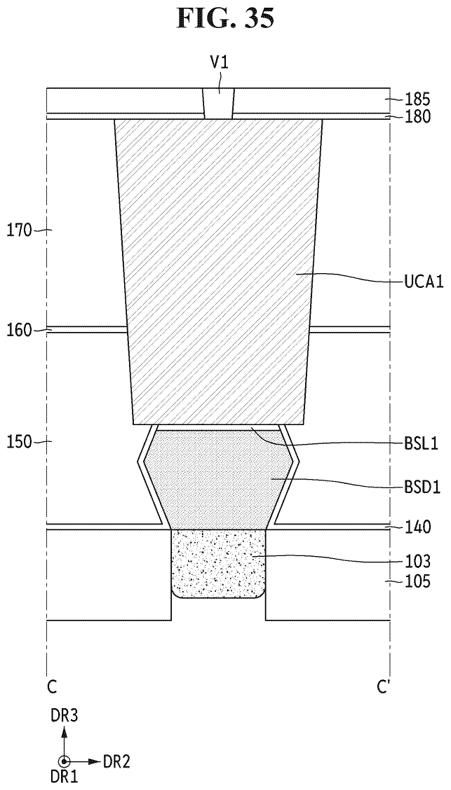

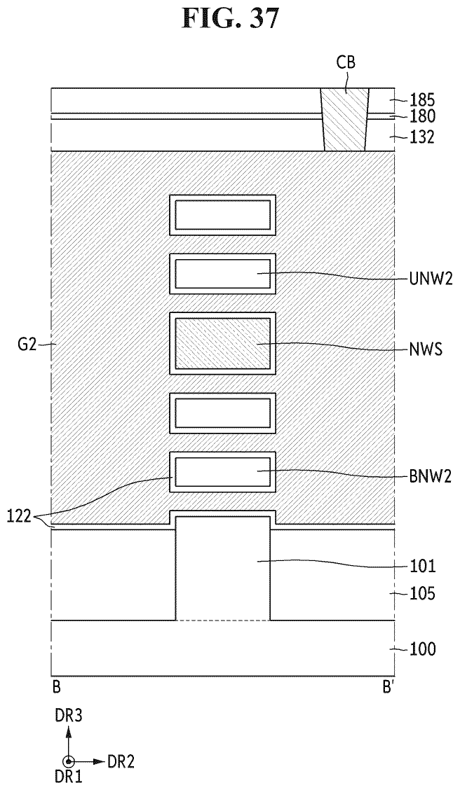

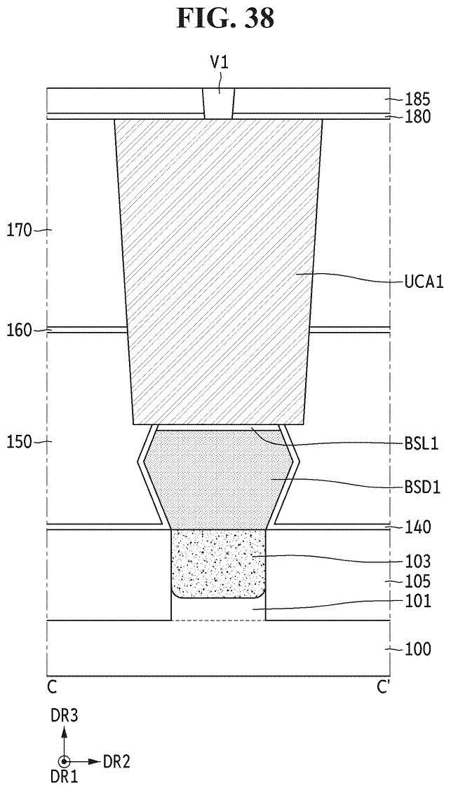

Hereinafter, a fabrication method of a semiconductor device according to some example embodiments of the present disclosure will be described with reference to FIGS. 2 to 39.

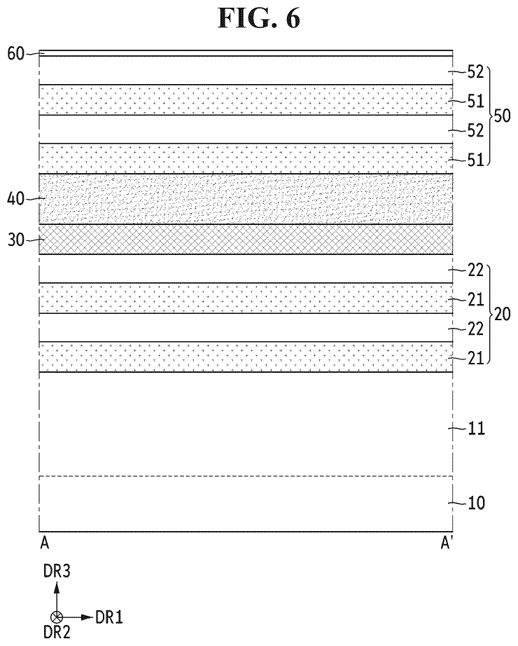

FIGS. 6 to 39 are intermediate stage diagrams for explaining the fabrication method of a semiconductor device according to some example embodiments of the present disclosure.

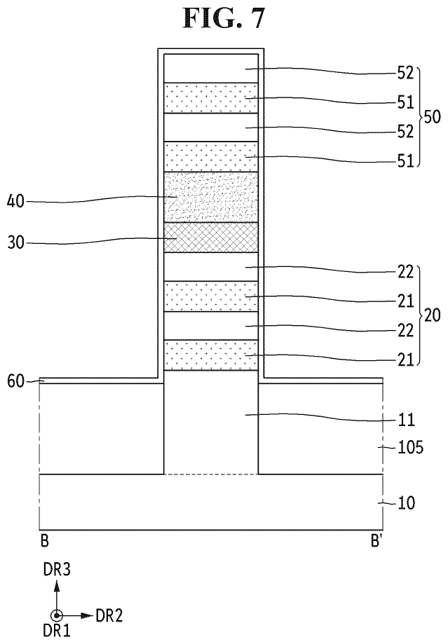

Referring to FIGS. 6 and 7, a first laminated structure 20, a third semiconductor layer 30, an isolation material layer 40, and a second laminated structure 50 may be sequentially stacked on a substrate 10. The substrate 10 may be a silicon substrate or SOI (silicon-on-insulator). Alternatively, the substrate 10 may include silicon germanium, SGOI (silicon germanium on insulator), indium antimonide, lead tellurium compound, indium arsenide, indium phosphide, gallium arsenide, or gallium antimonide, but the present disclosure is not limited thereto.

The first laminated structure 20 may be formed on the upper surface of the substrate 10. The first laminated structure 20 may include a first semiconductor layer 21 and a second semiconductor layer 22 alternately stacked on the upper surface of the substrate 10. For example, the first semiconductor layer 21 may be formed at a lowermost portion of the first laminated structure 20, and the second semiconductor layer 22 may be formed at an uppermost portion of the first laminated structure 20. The third semiconductor layer 30 may be formed on an upper surface of the first laminated structure 20. The isolation material layer 40 may be formed on the upper surface of the third semiconductor layer 30. The second laminated structure 50 may be formed on an upper surface of the isolation material layer 40. The second laminated structure 50 may include a fourth semiconductor layer 51 and a fifth semiconductor layer 52 alternately stacked on the upper surface of the isolation material layer 40. For example, the fourth semiconductor layer 51 may be formed at a lowermost portion of the second laminated structure 50, and the fifth semiconductor layer 52 may be formed at an uppermost portion of the second laminated structure 50.

For example, each of the second semiconductor layer 22 and the fifth semiconductor layer 52 may include silicon (Si). For example, each of the first semiconductor layer 21, the third semiconductor layer 30, the isolation material layer 40, and the fourth semiconductor layer 51 may include silicon germanium (SiGe). For example, the concentration of germanium (Ge) included in the third semiconductor layer 30 may be greater than the concentration of germanium (Ge) included in each of the first semiconductor layer 21 and the fourth semiconductor layer 51. Additionally, the concentration of germanium (Ge) included in the isolation material layer 40 may be greater than the concentration of germanium (Ge) included in the third semiconductor layer 30.

Subsequently, a portion of each of the first laminated structure 20, the third semiconductor layer 30, the isolation material layer 40, and the second laminated structure 50 may be etched. While a portion of each of the first laminated structure 20, the third semiconductor layer 30, the isolation material layer 40, and the second laminated structure 50 is being etched, a portion of the substrate 10 may also be etched. Through such an etching process, an active pattern 11 may be defined beneath the first laminated structure 20 on the upper surface of the substrate 10. The active pattern 11 may protrude in the vertical direction DR3 from the upper surface of the substrate 10. The active pattern 11 may extend in the first horizontal direction DR1.

Subsequently, the field insulating layer 105 may be formed on the upper surface of the substrate 10. The field insulating layer 105 may surround or extend around the sidewall of the active pattern 11 in plan view. For example, the upper surface of the active pattern 11 may be formed higher than the upper surface of the field insulating layer 105. Subsequently, a pad oxide layer 60 may be formed to cover, overlap, or be on the upper surface of the field insulating layer 105, the exposed sidewall of the active pattern 11, the sidewall of the first laminated structure 20, the sidewall of the third semiconductor layer 30, the sidewall of the isolation material layer 40, and the sidewall and the upper surface of the second laminated structure 50. For example, the pad oxide layer 60 may be formed conformally. The pad oxide layer 60 may comprise, for example, silicon oxide (SiO₂).

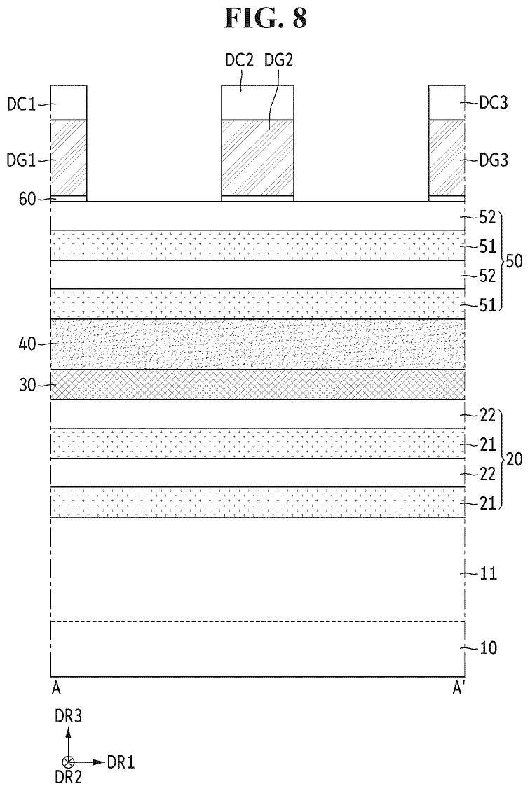

Referring to FIGS. 8 to 10, first, second, and third dummy gates DG1, DG2, DG3 and first, second, and third dummy capping patterns DC1, DC2, DC3 extending in the second horizontal direction DR2 may be formed on the pad oxide layer 60 on the second laminated structure 50 and the field insulating layer 105. For example, the second dummy gate DG2 may be spaced apart from the first dummy gate DG1 in the first horizontal direction DR1. The third dummy gate DG3 may be spaced apart from the second dummy gate DG2 in the first horizontal direction DR1. The first dummy capping pattern DC1 may be disposed on the first dummy gate DG1. The second dummy capping pattern DC2 may be disposed on the second dummy gate DG2. The third dummy capping pattern DC3 may be disposed on the third dummy gate DG3. While the first, second, and third dummy gates DG1, DG2, DG3 and the first, second, and third dummy capping patterns DC1, DC2, DC3 are being formed, the remaining of the pad oxide layer 60 on the substrate 10 may be removed except for the portion overlapping with each of the first, second, and third dummy gates DG1, DG2, DG3 in the vertical direction DR3.

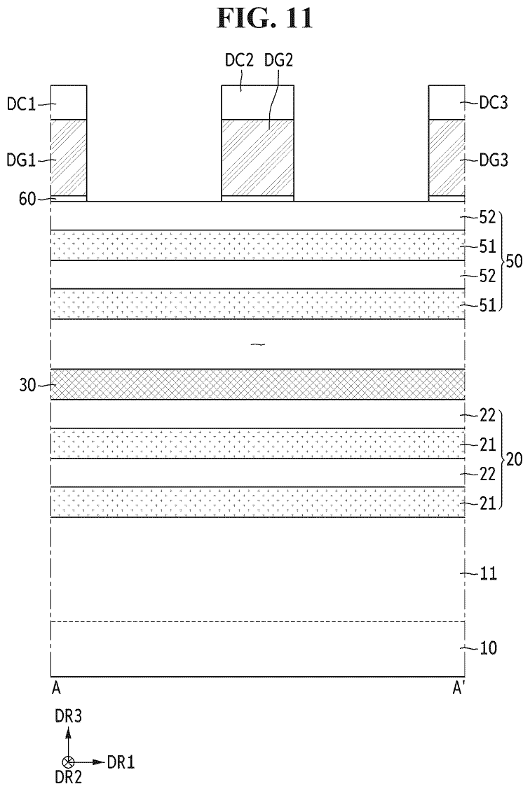

Referring to FIGS. 11 to 13, the isolation material layer 40 (see FIGS. 8 to 10) may be etched. For example, the isolation material layer 40 (see FIGS. 8 to 10) may be etched by a wet etching process.

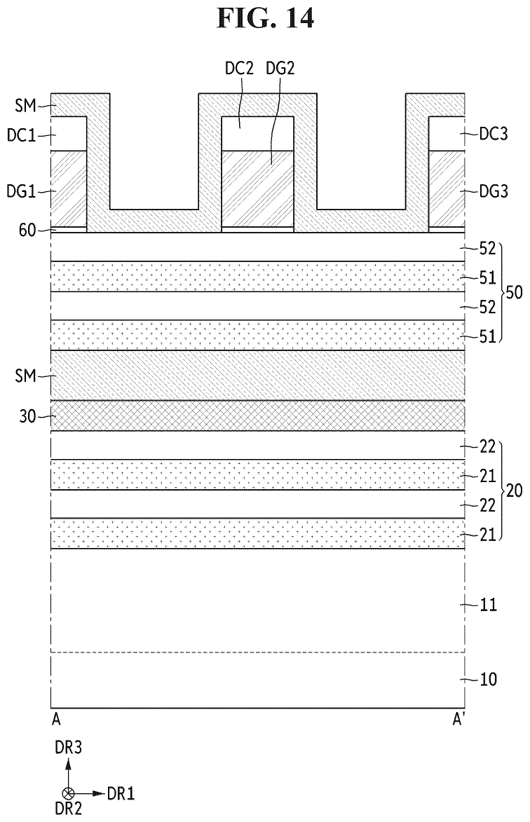

Referring to FIGS. 14 to 16, a spacer material layer SM may be formed to cover, overlap, or be on the sidewall of each of the first, second, and third dummy gates DG1, DG2, DG3, the sidewall and upper surface of each of the first, second, and third dummy capping patterns DC1, DC2, DC3, the first laminated structure 20, the third semiconductor layer 30, the second laminated structure 50, and the upper surface of the field insulating layer 105. The spacer material layer SM may partially or completely fill the portion where the isolation material layer 40 (see FIGS. 8 to 10) is etched. For example, the spacer material layer SM may be formed conformally. For example, the spacer material layer SM may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and/or combinations thereof.

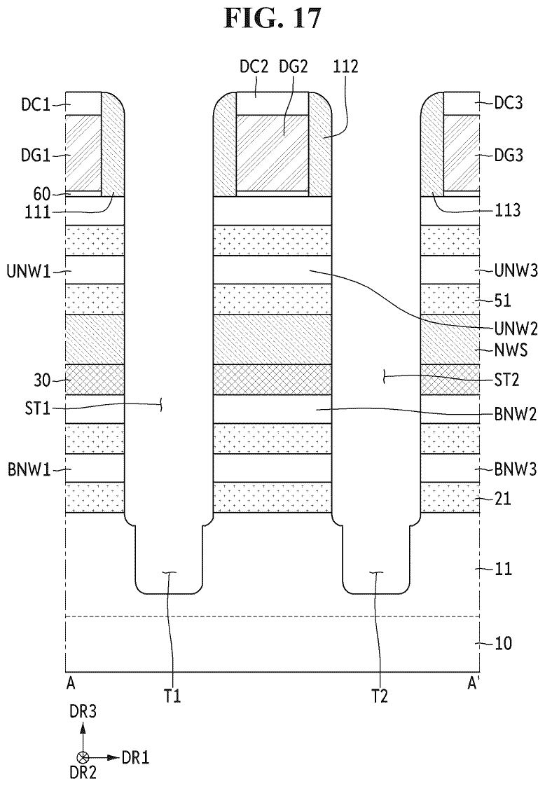

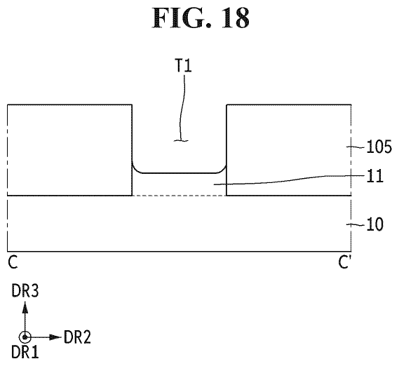

Referring to FIGS. 17 and 18, the first, second, and third dummy capping patterns DC1, DC2, DC3 and the first, second, and third dummy gates DG1, DG2, DG3 may be used as masks to etch the first laminated structure 20 (see FIGS. 14 to 16), the third semiconductor layer 30, the second laminated structure 50 (see FIGS. 14 to 16), and the spacer material layer SM (see FIGS. 14 to 16), thereby forming the first and second source/drain trenches ST1, ST2. For example, the first source/drain trench ST1 may be formed between the first dummy gate DG1 and the second dummy gate DG2. The second source/drain trench ST2 may be formed between the second dummy gate DG2 and the third dummy gate DG3.

Subsequently, a first sacrificial pattern trench T1 may be formed at the lower portion of the first source/drain trench ST1, and a second sacrificial pattern trench T2 may be formed at the lower portion of the second source/drain trench ST2. For example, each of the first and second sacrificial pattern trenches T1, T2 may be formed inside the active pattern 11. For example, the width of each of the first and second sacrificial pattern trenches T1, T2 in the first horizontal direction DR1 may be smaller than the width of each of the first and second source/drain trenches ST1, ST2 in the first horizontal direction DR1. However, the present disclosure is not limited thereto.

For example, while each of the first and second source/drain trenches ST1, ST2 is being formed, the spacer material layer SM (see FIGS. 14 to 16) formed on the upper surface of each of the first, second, and third dummy capping patterns DC1, DC2, DC3 and a portion of each of the first, second, and third dummy capping patterns DC1, DC2, DC3 may be etched. The spacer material layer SM (see FIGS. 14 to 16) remaining on the sidewall of each of the first, second, and third dummy gates DG1, DG2, DG3 and the remaining portions of the first, second, and third dummy capping patterns DC1, DC2, DC3 may be defined as the first, second, and third gate spacers 111, 112, 113.

For example, after each of the first and second source/drain trenches ST1, ST2 is formed, the second semiconductor layer 22 (see FIGS. 14 to 16) remaining beneath each of the first, second, and third dummy gates DG1, DG2, DG3 may be defined as the first, second, and third plurality of bottom nanosheets BNW1, BNW2, BNW3, respectively. Additionally, after each of the first and second source/drain trenches ST1, ST2 are formed, the fifth semiconductor layer 52 (see FIGS. 14 to 16) remaining beneath each of the first, second, and third dummy gates DG1, DG2, DG3 may be defined as the first, second, and third plurality of upper nanosheets UNW1, UNW2, UNW3, respectively. For example, after each of the first and second source/drain trenches ST1, ST2 is formed, the spacer material layer SM (see FIGS. 14 to 16) remaining between each of the first, second, and third plurality of bottom nanosheets BNW1, BNW2, BNW3 and each of the first, second, and third plurality of upper nanosheets UNW1, UNW2, UNW3 may be defined as the nanosheet isolation layer NWS.

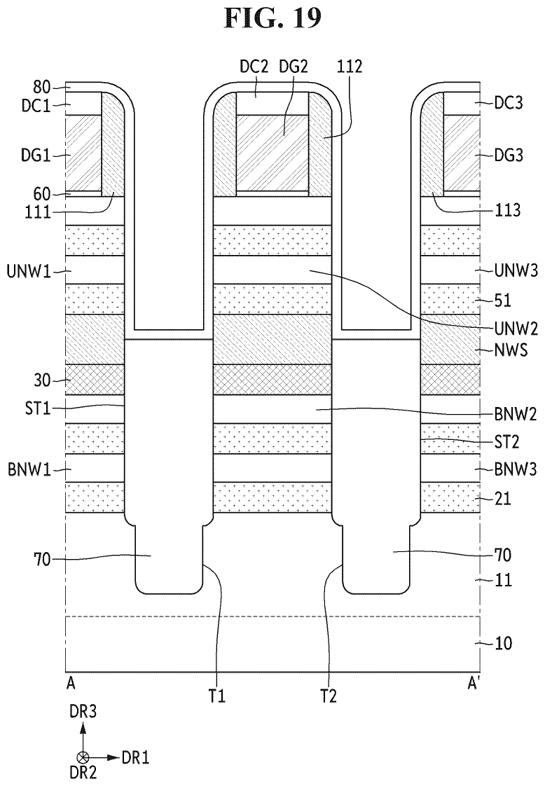

Referring to FIG. 19, a protective layer 70 may be formed inside each of the first and second sacrificial pattern trenches T1, T2, and the first and second source/drain trenches ST1, ST2. For example, the protective layer 70 may include a SOH (Spin On Hardmask). Subsequently, a portion of the protective layer 70 may be etched. For example, after a portion of the protective layer 70 is etched, the upper surface of the remaining protective layer 70 may be formed between the bottom surface of the nanosheet isolation layer NWS and the upper surface of the nanosheet isolation layer NWS.

Then, a liner layer 80 may be formed on the sidewalls of the first and second source/drain trenches ST1, ST2 and on the upper surface of the protective layer 70, respectively. For example, the liner layer 80 may also be formed on the sidewalls of the first, second, and third gate spacers 111, 112, 113 and on the upper surfaces of the first, second, and third dummy capping patterns DC1, DC2, DC3, respectively. For example, the liner layer 80 may be formed conformally. For example, the liner layer 80 may include silicon nitride (SiN), silicon carbonitride (SiCN), or silicon boron carbonitride (SiBCN).

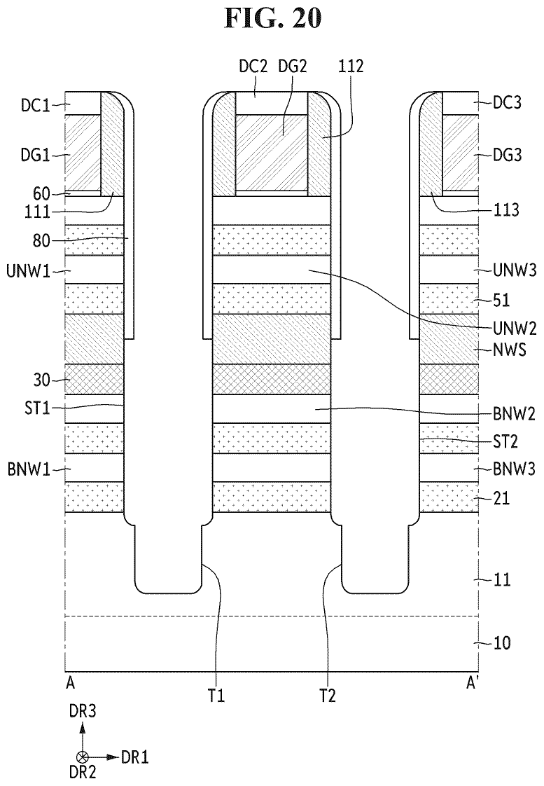

Referring to FIG. 20, by performing an etch back process, a portion of the liner layer 80 may be etched to expose the upper surface of the protective layer 70 (see FIG. 19). For example, after the etch back process is performed, the upper surface of each of the first, second, and third dummy capping patterns DC1, DC2, and DC3 may be exposed. Subsequently, the protective layer 70 (see FIG. 19) may be etched.

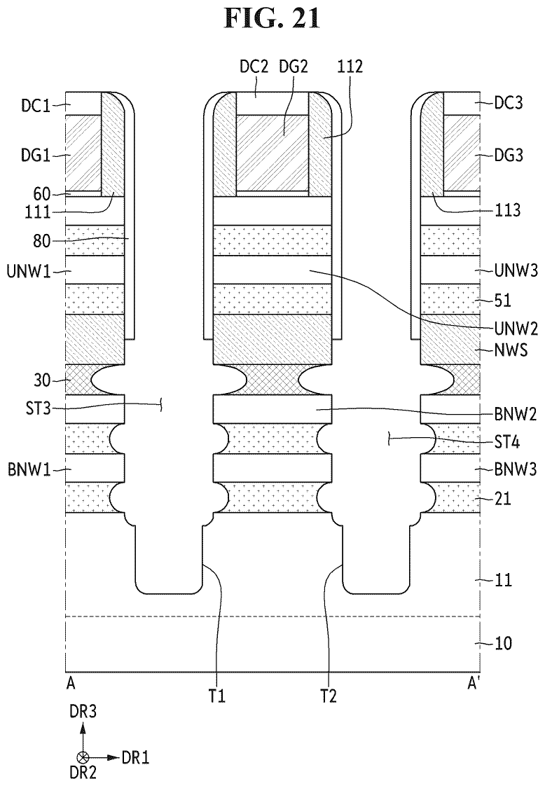

Referring to FIG. 21, a portion of the sidewall in the first horizontal direction DR1 of each of the first semiconductor layer 21 and the third semiconductor layer 30 exposed inside each of the first and second source/drain trenches ST1, ST2 (see FIG. 20) may be etched by performing a wet etch process. For example, the third semiconductor layer 30 may be etched more than the first semiconductor layer 21. That is, the sidewall of the third semiconductor layer 30 in the first horizontal direction DR1 may be formed more concave toward the center than the sidewall of the first semiconductor layer 21 in the first horizontal direction DR1. After the etching process is performed on a portion of each of the first semiconductor layer 21 and the third semiconductor layer 30, the region formed in the first sacrificial pattern trench T1 may be defined as the third source/drain trench ST3, and the region formed in the second sacrificial pattern trench T2 may be defined as the fourth source/drain trench ST4.

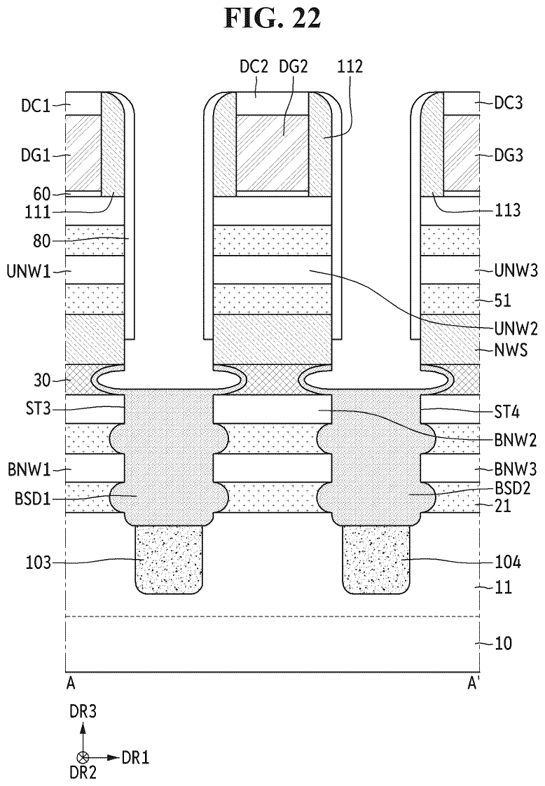

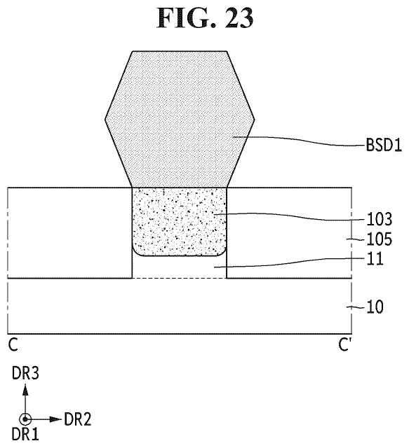

Referring to FIGS. 22 and 23, the first sacrificial pattern 103 may be formed inside the first sacrificial pattern trench T1 (see FIG. 21), and the second sacrificial pattern 104 may be formed inside the second sacrificial pattern trench T2 (see FIG. 21). For example, each of the first and second sacrificial patterns 103, 104 may include silicon germanium (SiGe).

Subsequently, inside the third source/drain trench ST3, the first bottom source/drain region BSD1 may be formed on the sidewall of each of the first and second plurality of bottom nanosheets BNW1, BNW2, the first semiconductor layer 21 and the third semiconductor layer 30 in the first horizontal direction DR1. For example, inside the third source/drain trench ST3, the first bottom source/drain region BSD1 may be formed along the sidewall of the third semiconductor layer 30 in the first horizontal direction DR1. Additionally, inside the fourth source/drain trench ST4, the second bottom source/drain region BSD2 may be formed on the sidewall of each of the second and third plurality of bottom nanosheets BNW2, BNW3, the first semiconductor layer 21 and the third semiconductor layer 30 in the first horizontal direction DR1. For example, inside the fourth source/drain trench ST4, the second bottom source/drain region BSD2 may be formed along the sidewall of the third semiconductor layer 30 in the first horizontal direction DR1.

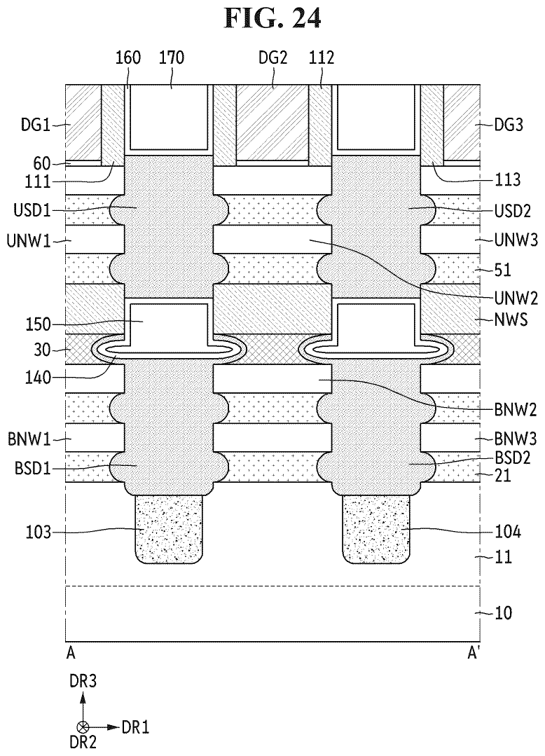

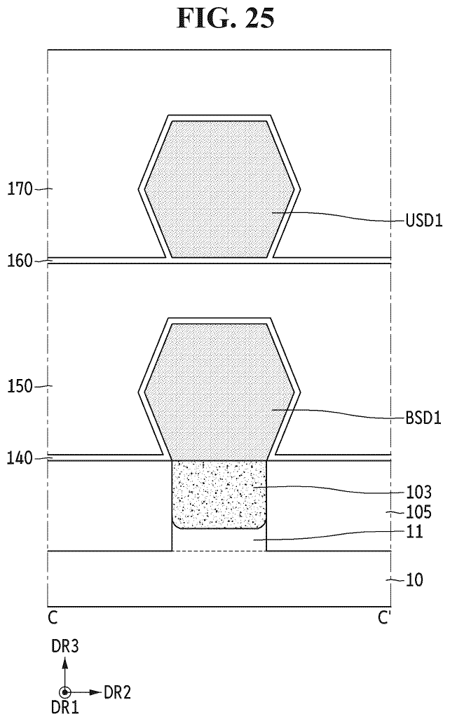

Referring to FIGS. 24 and 25, the first etching stop layer 140 may be formed on the exposed surface of each of the field insulating layer 105, the first and second bottom source/drain regions BSD1, BSD2, the nanosheet isolation layer NWS, and the liner layer 80 (see FIG. 22). For example, the first etching stop layer 140 may be formed conformally. For example, at least a portion of the first etching stop layer 140 may be formed between the upper surface of the uppermost nanosheet of each of the first, second, and third plurality of bottom nanosheets BNW1, BNW2, BNW3 and the bottom surface of the nanosheet isolation layer NWS. Subsequently, the first upper interlayer insulating layer 150 may be formed on the first etching stop layer 140. For example, at least a portion of the first upper interlayer insulating layer 150 may be formed between the upper surface of the uppermost nanosheet of each of the first, second, and third plurality of bottom nanosheets BNW1, BNW2, BNW3 and the bottom surface of the nanosheet isolation layer NWS.

Subsequently, a portion of the first upper interlayer insulating layer 150 may be etched. For example, after a portion of the first upper interlayer insulating layer 150 is etched, the upper surface of the remaining first upper interlayer insulating layer 150 may be formed lower than the upper surface of the nanosheet isolation layer NWS. Subsequently, a portion of the first etching stop layer 140 and the liner layer 80 (see FIG. 22) exposed on the upper surface of the first upper interlayer insulating layer 150 may be etched. As a result, the sidewall in the first horizontal direction DR1 of each of the first, second, and third plurality of upper nanosheets UNW1, UNW2, UNW3, and the fourth semiconductor layer 51 may be exposed on the upper surface of the first upper interlayer insulating layer 150.

Subsequently, the first upper source/drain region USD1 may be formed between the first plurality of upper nanosheets UNW1 and the second plurality of upper nanosheets UNW2. Additionally, the second upper source/drain region USD2 may be formed between the second plurality of upper nanosheets UNW2 and the third plurality of upper nanosheets UNW3. Subsequently, the second etching stop layer 160 may be formed on the upper surface of the first upper interlayer insulating layer 150, on the exposed surfaces of the first and second upper source/drain regions USD1, USD2, and on the sidewall of each of the first, second, and third gate spacers 111, 112, 113. Subsequently, the second upper interlayer insulating layer 170 may be formed on the second etching stop layer 160. Subsequently, a planarization process may be performed to expose an upper surface of each of the first, second, and third dummy gates DG1, DG2, DG3.

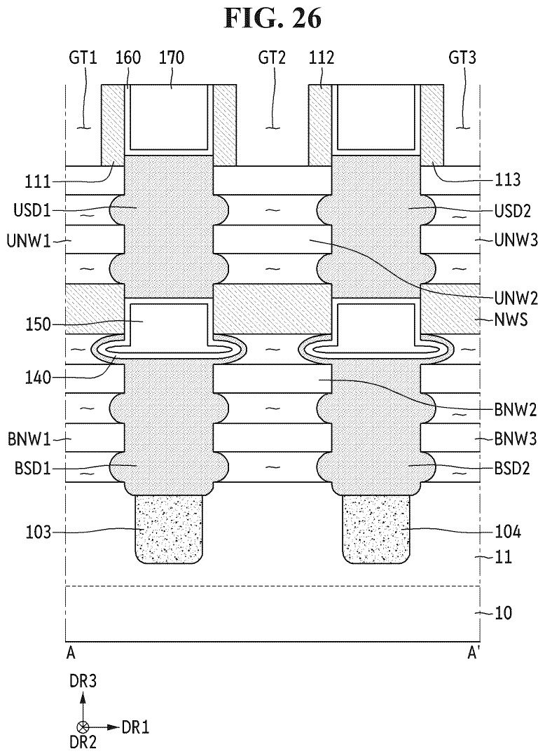

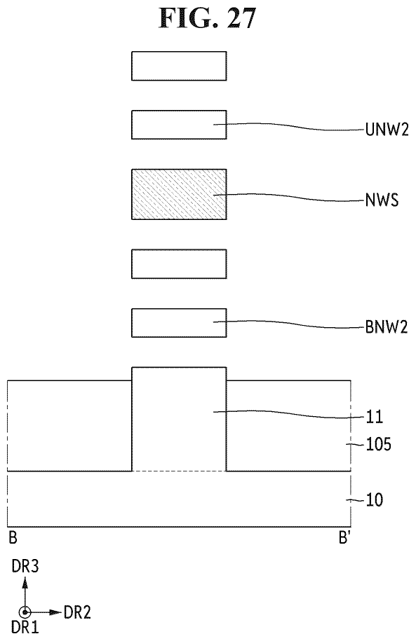

Referring to FIGS. 26 and 27, each of the first, second, and third dummy gates DG1, DG2, DG3 (see FIG. 24), the pad oxide layer 60 (see FIG. 24), the first semiconductor layer 21 (see FIG. 24), the third semiconductor layer 30 (see FIG. 24), and the fourth semiconductor layer 51 (see FIG. 24) may be etched. For example, the etched portion of each of the first dummy gate DG1 (see FIG. 24), the pad oxide layer 60 (see FIG. 24), the first semiconductor layer 21 (see FIG. 24), the third semiconductor layer 30 (see FIG. 24), and the fourth semiconductor layer 51 (see FIG. 24) may be defined as the first gate trench GT1. The etched portion of each of the second dummy gate DG2 (see FIG. 24), the pad oxide layer 60 (see FIG. 24), the first semiconductor layer 21 (see FIG. 24), the third semiconductor layer 30 (see FIG. 24), and the fourth semiconductor layer 51 (see FIG. 24) may be defined as the second gate trench GT2. The etched portion of each of the third dummy gate DG3 (see FIG. 24), the pad oxide layer 60 (see FIG. 24), the first semiconductor layer 21 (see FIG. 24), the third semiconductor layer 30 (see FIG. 24), and the fourth semiconductor layer 51 (see FIG. 24) may be defined as the third gate trench GT3.

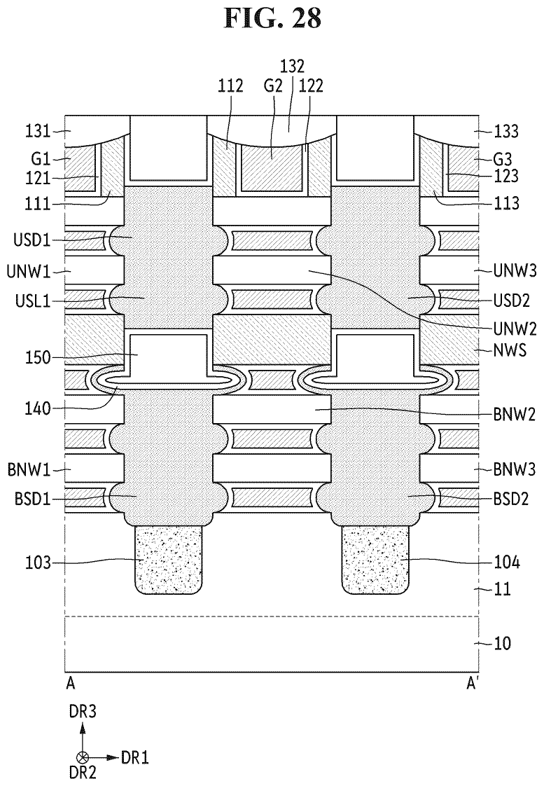

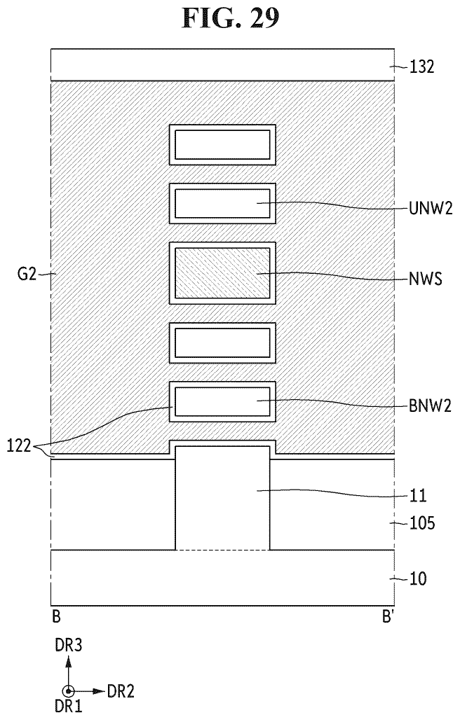

Referring to FIGS. 28 and 29, the first gate insulating layer 121, the first gate electrode G1, and the first capping pattern 131 may be formed inside the first gate trench GT1 (see FIG. 26). Further, the second gate insulating layer 122, the second gate electrode G2, and the second capping pattern 132 may be formed inside the second gate trench GT2 (see FIG. 26). Further, the third gate insulating layer 123, the third gate electrode G3, and the third capping pattern 133 may be formed inside the third gate trench GT3 (see FIG. 26).

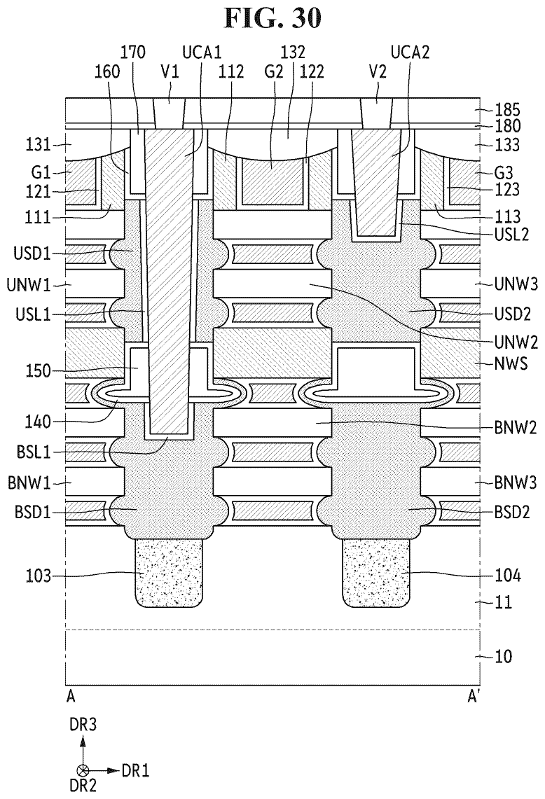

Referring to FIGS. 30 to 32, the first upper source/drain contact UCA1 penetrating or extending into the second upper interlayer insulating layer 170, the second etching stop layer 160, the first upper source/drain region USD1, the first etching stop layer 140, and the first upper interlayer insulating layer 150 in the vertical direction DR3 and extending into the inside of the first bottom source/drain region BSD1 may be formed. Further, the second upper source/drain contact UCA2 penetrating the second upper interlayer insulating layer 170 and the second etching stop layer 160 in the vertical direction DR3 and extending into the inside of the second upper source/drain region USD2 may be formed.

Additionally, the first bottom silicide layer BSL1 may be formed along the interface between the first bottom source/drain region BSD1 and the first upper source/drain contact UCA1. The first upper silicide layer USL1 may be formed along the interface between the first upper source/drain region USD1 and the first upper source/drain contact UCA1. The second upper silicide layer USL2 may be formed along the interface between the second upper source/drain region USD2 and the second upper source/drain contact UCA2.

Subsequently, the third etching stop layer 180 and the third upper interlayer insulating layer 185 may be formed sequentially on the upper surface of each of the first, second, and third capping patterns 131, 132, 133, the second upper interlayer insulating layer 170, and the first and second upper source/drain contacts UCA1, UCA2. Subsequently, the gate contact CB penetrating the third upper interlayer insulating layer 185, the third etching stop layer 180, and the second capping pattern 132 in the vertical direction DR3 and connecting to the second gate electrode G2 may be formed. Further, the first via V1 penetrating the third upper interlayer insulating layer 185 and the third etching stop layer 180 in the vertical direction DR3 and connecting to the first upper source/drain contact UCA1 may be formed. The second via V2 penetrating the third upper interlayer insulating layer 185 and the third etching stop layer 180 in the vertical direction DR3 and connecting to the second upper source/drain contact UCA2 may be formed.

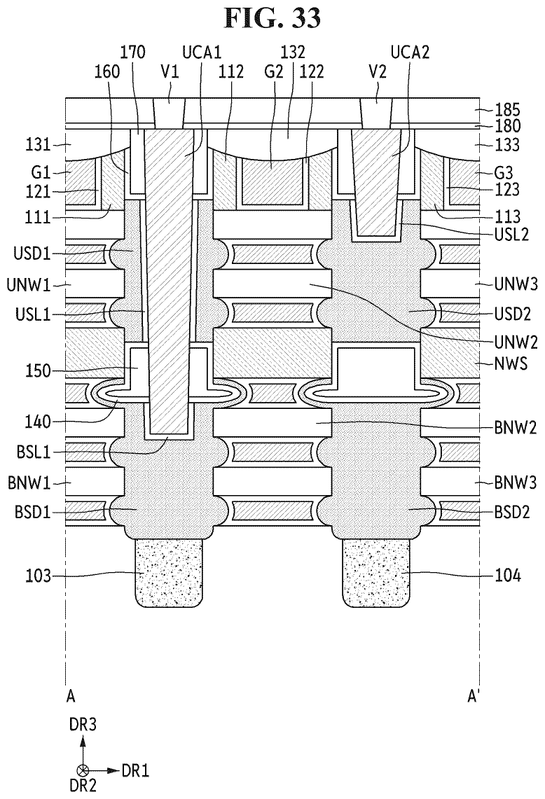

Referring to FIGS. 33 to 35, the substrate 10 (see FIGS. 30 to 32) and the active pattern 11 (see FIGS. 30 to 32) may each be etched.

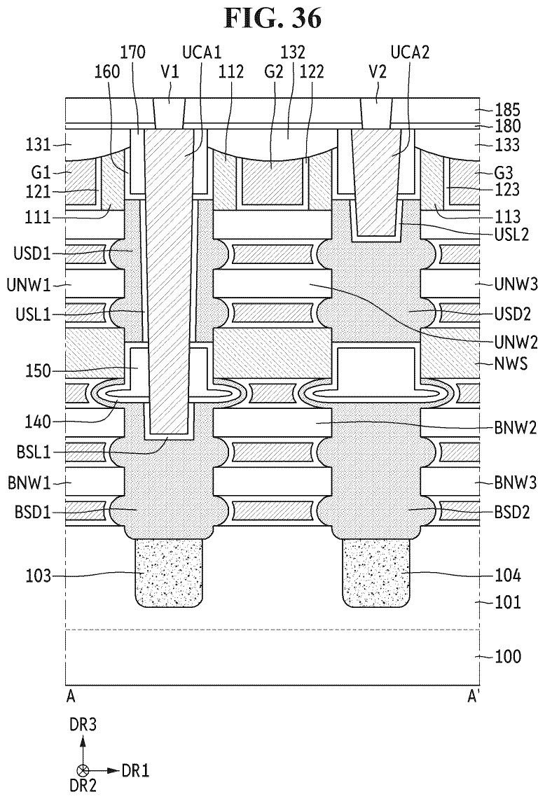

Referring to FIGS. 36 to 38, the insulating pattern 101 may be formed on the portion where the active pattern 11 (see FIGS. 30 to 32) is etched, and the lower interlayer insulating layer 100 may be formed on the portion where the substrate 10 (see FIGS. 30 to 32) is etched.

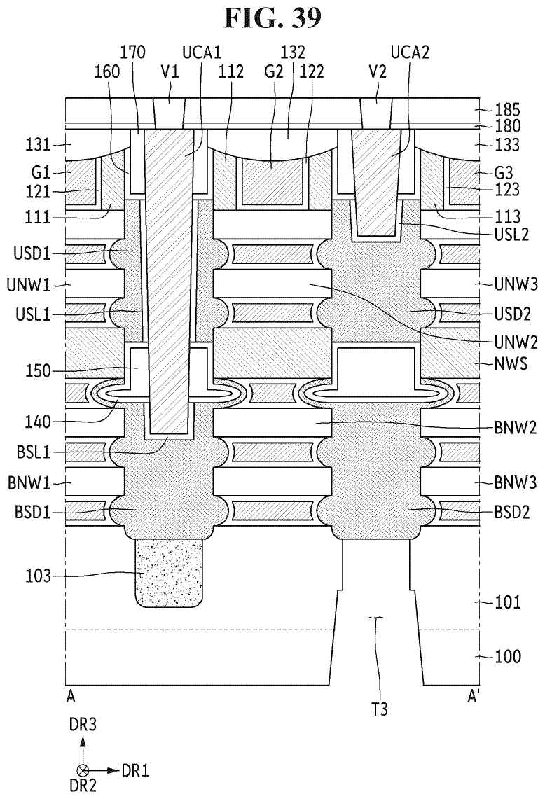

Referring to FIG. 39, a first bottom contact trench penetrating or extending into a portion of the lower interlayer insulating layer 100 and insulating pattern 101 in the vertical direction DR3 may be formed. For example, the second sacrificial pattern 104 (see FIG. 36) may be exposed through the first bottom contact trench. Subsequently, the second sacrificial pattern 104 (see FIG. 36) may be etched through the first bottom contact trench. The region including the portion where the second sacrificial pattern 104 (see FIG. 36) is etched and the first bottom contact trench may be defined as the second bottom contact trench T3. For example, the bottom surface of the second bottom source/drain region BSD2 may be exposed through the second bottom contact trench T3.

Referring to FIGS. 2 to 5, the bottom source/drain contact BCA may be formed inside the second bottom contact trench T3 (see FIG. 39). Additionally, the second bottom silicide layer BSL2 may be formed along the interface between the second bottom source/drain region BSD2 and the bottom source/drain contact BCA. Through such a fabrication process, the semiconductor device illustrated in FIGS. 2 to 5 may be fabricated.

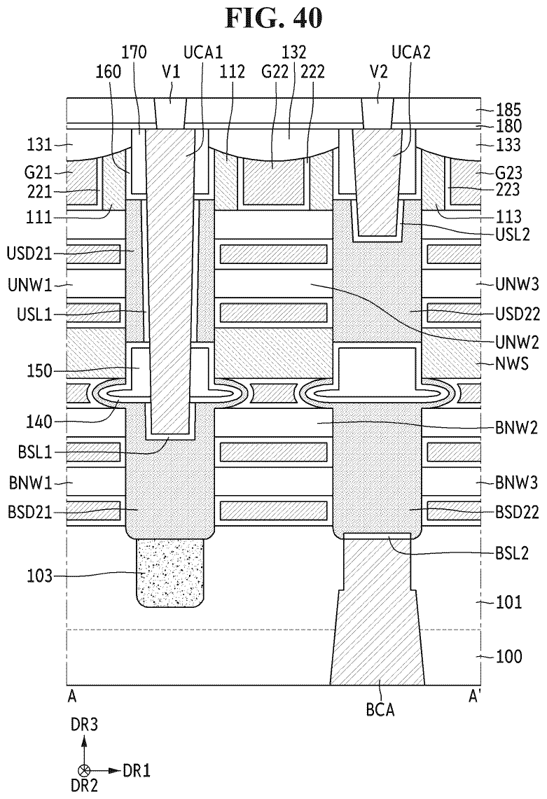

Hereinafter, the semiconductor devices according to some embodiments of the present disclosure will be described with reference to FIG. 40. The description will focus on the differences from the semiconductor device illustrated in FIGS. 1 to 5.

FIG. 40 is a cross-sectional view for explaining the semiconductor device according to some other example embodiments of the present disclosure.

Referring to FIG. 40, in the semiconductor device according to some other example embodiments of the present disclosure, the sidewall of the second plurality of bottom nanosheets BNW2 in the first horizontal direction DR1 and the sidewall of the second gate insulating layer 222 in the first horizontal direction DR1 may have a continuous sloped profile.

For example, the sidewall of the second plurality of bottom nanosheets BNW2 in the first horizontal direction DR1 may have a sloped profile that is continuous with the sidewall of the second gate insulating layer 222 in the first horizontal direction DR1 that is in contact with the first bottom source/drain region BSD21 between adjacent the second plurality of bottom nanosheets BNW2. Further, the sidewalls of the second plurality of bottom nanosheets BNW2 in the first horizontal direction DR1 may have a sloped profile that is continuous with the sidewall of the second gate insulating layer 222 in the first horizontal direction DR1 that is in contact with the second bottom source/drain region BSD22 between adjacent the second plurality of bottom nanosheets BNW2.

For example, the sidewall of the second plurality of upper nanosheets UNW2 in the first horizontal direction DR1 may have a sloped profile that is continuous with the sidewall of the second gate insulating layer 222 in the first horizontal direction DR1 that is in contact with the first upper source/drain region USD21 between adjacent the second plurality of upper nanosheets UNW2. Additionally, the sidewall of the second plurality of upper nanosheets UNW2 in the first horizontal direction DR1 may have a sloped profile that is continuous with the sidewall of the second gate insulating layer 222 in the first horizontal direction DR1 that is in contact with the second upper source/drain region USD22 between adjacent the second plurality of upper nanosheets UNW2.

For example, the second gate electrode G22 may surround or extend around each of the second plurality of bottom nanosheets BNW2, the nanosheet isolation layer NWS, and the second plurality of upper nanosheets UNW2. Each of the first and third gate insulating layers 221, 223 may have a similar structure to the second gate insulating layer 222. Further, each of the first and third gate electrodes G21, G23 may have a similar structure to the second gate electrode G22. Therefore, a detailed description of each of the first and third gate insulating layers 221, 223 and the first and third gate electrodes G21, G23 may be omitted.

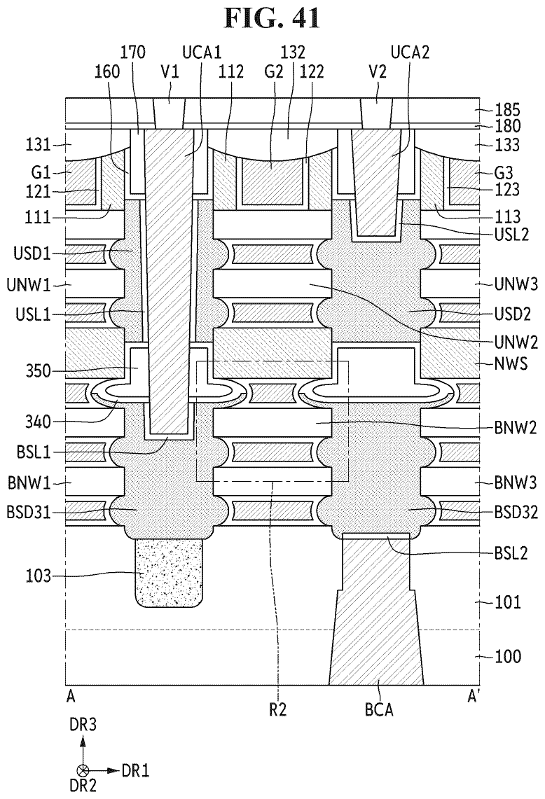

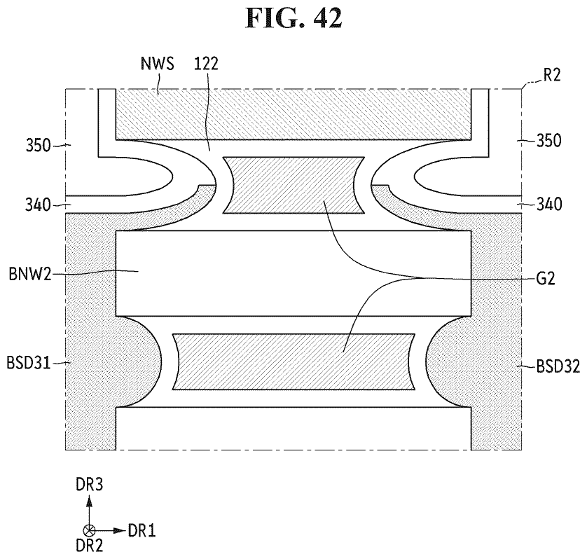

Hereinafter, the semiconductor device according to several other example embodiments of the present disclosure will be described with reference to FIGS. 41 and 42. The description will focus on the differences from the semiconductor devices illustrated in FIGS. 1 to 5.

FIG. 41 is a cross-sectional view for explaining the semiconductor device according to some other example embodiments of the present disclosure. FIG. 42 is an enlarged view of the R2 region of FIG. 41.

Referring to FIGS. 41 and 42, in the semiconductor device according to another several embodiments of the present disclosure, the first etching stop layer 340 may be in contact with the bottom surface of the nanosheet isolation layer NWS.

For example, between the upper surface of the uppermost nanosheet of each of the first, second, and third plurality of bottom nanosheets BNW1, BNW2, BNW3 and the bottom surface of the nanosheet isolation layer NWS, the first etching stop layer 340 may be in contact with the uppermost surface of each of the first and second bottom source/drain regions BSD31, BSD32. For example, between the upper surface of the uppermost nanosheet of each of the first and third plurality of bottom nanosheets BNW1, BNW2, BNW3 and the bottom surface of the nanosheet isolation layer NWS, the first etching stop layer 340 may be in contact with each of the first and third gate insulating layers 121, 122, 123. For example, at least a portion of the first upper interlayer insulating layer 350 may be disposed between the upper surface of the uppermost nanosheet of each of the first, second, and third plurality of bottom nanosheets BNW1, BNW2, BNW3 and the bottom surface of the nanosheet isolation layer NWS.

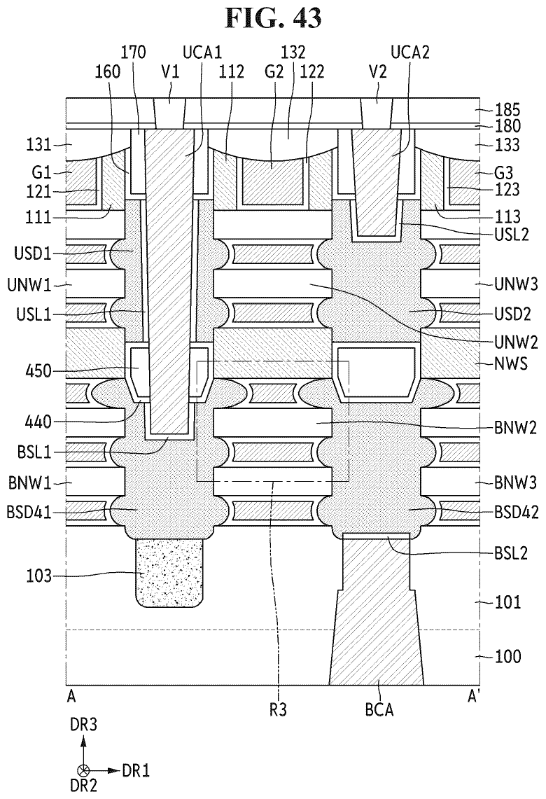

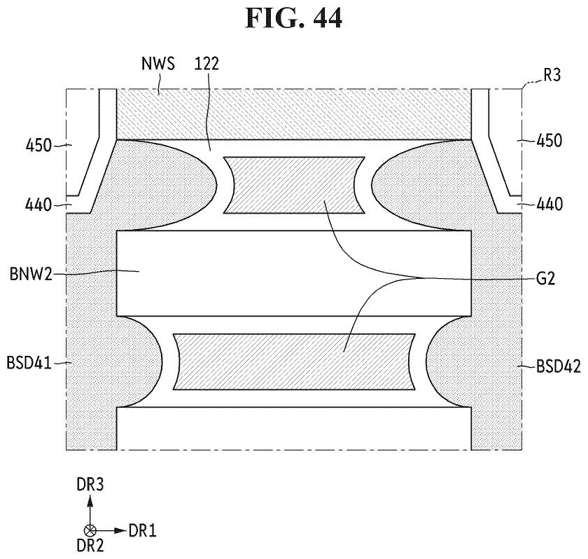

Hereinafter, the semiconductor device according to some other example embodiments of the present disclosure will be described with reference to FIGS. 43 and 44. The description will focus on the differences from the semiconductor device illustrated in FIGS. 1 to 5.

FIG. 43 is a cross-sectional view for explaining the semiconductor device according to some other example embodiments of the present disclosure. FIG. 44 is an enlarged view of the R3 region of FIG. 43.

Referring to FIGS. 43 and 44, in the semiconductor device according to some other example embodiments of the present disclosure, each of the first etching stop layer 440 and the first upper interlayer insulating layer 450 is not disposed between the upper surface of the uppermost nanosheet of each of the first, second, and third plurality of bottom nanosheets BNW1, BNW2, BNW3 and the bottom surface of the nanosheet isolation layer NWS.

For example, between the upper surface of the uppermost nanosheet of each of the first and second plurality of bottom nanosheets BNW1, BNW2 and the bottom surface of the nanosheet isolation layer NWS, the first bottom source/drain region BSD41 may completely fill the region on the sidewall of each of the first and second gate insulating layers 121, 122 in the first horizontal direction DR1. Further, between the upper surface of the uppermost nanosheet of each of the second and third plurality of bottom nanosheets BNW2, BNW3 and the bottom surface of the nanosheet isolation layer NWS, the second bottom source/drain region BSD42 may completely fill the region on the sidewall of each of the second and third gate insulating layers 122, 123 in the first horizontal direction DR1.

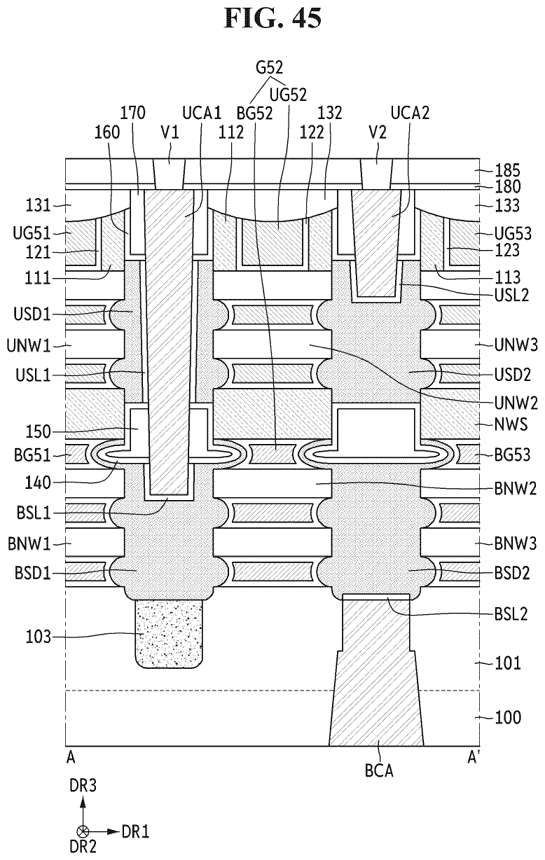

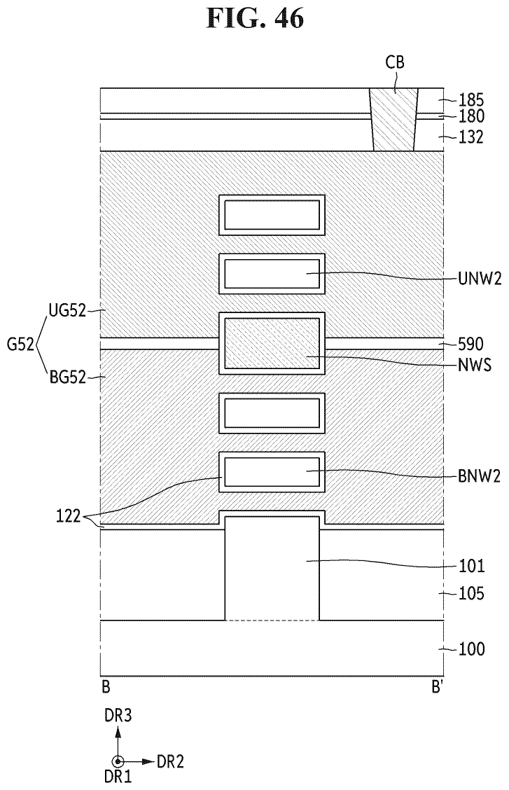

Hereinafter, the semiconductor device according to some other example embodiments of the present disclosure will be described with reference to FIGS. 45 and 46. The description will focus on the differences from the semiconductor device illustrated in FIGS. 1 to 5.

FIGS. 45 and 46 are cross-sectional views for explaining the semiconductor device according to some other example embodiments of the present disclosure.

Referring to FIGS. 45 and 46, in the semiconductor device according to some other example embodiments of the present disclosure, the second gate electrode G52 may include the second bottom gate electrode BG52 and the second upper gate electrode UG52, which are separated in the vertical direction DR3.

For example, the second bottom gate electrode BG52 may surround or extend around the second plurality of bottom nanosheets BNW2 and a portion of the nanosheet isolation layer NWS. The second upper gate electrode UG52 may be spaced apart from the second bottom gate electrode BG52 in the vertical direction DR3. The second upper gate electrode UG52 may surround or extend around another portion of the nanosheet isolation layer NWS and the second plurality of upper nanosheets UNW2. For example, a gate isolation layer 590 may be disposed between the second bottom gate electrode BG52 and the second upper gate electrode UG52. For example, the gate isolation layer 590 may include an insulating material. However, the present disclosure is not limited thereto. In some other example embodiments, the gate isolation layer 590 may include a conductive material.

For example, the first bottom gate electrode BG51 may surround or extend around the first plurality of bottom nanosheets BNW1 and a portion of the nanosheet isolation layer NWS. The first upper gate electrode UG51 may be spaced apart from the first bottom gate electrode BG51 in the vertical direction DR3. The first upper gate electrode UG51 may surround another portion of the nanosheet isolation layer NWS and the first plurality of upper nanosheets UNW1. For example, the third bottom gate electrode BG53 may surround the third plurality of bottom nanosheets BNW3 and a portion of the nanosheet isolation layer NWS. The third upper gate electrode UG53 may be spaced apart from the third bottom gate electrode BG53 in the vertical direction DR3. The third upper gate electrode UG53 may surround or extend around another portion of the nanosheet isolation layer NWS and the third plurality of upper nanosheets UNW3.

While example embodiments according to the present disclosure have been described above with reference to the accompanying drawings, it will be understood that the present disclosure is not limited to the above embodiments and may be fabricated in a variety of different forms, and those of ordinary skill in the art to which the present disclosure belongs, may recognize that it may be implemented in other specific forms without changing the technical idea or the features of the present disclosure. Therefore, it should be understood that the above-described embodiments are example in all respects and not restrictive.

What is claimed is:

1. A semiconductor device comprising:
a lower interlayer insulating layer;
an insulating pattern extending in a first direction on an upper surface of the lower interlayer insulating layer;
a plurality of bottom nanosheets spaced apart from each other in a third direction on the insulating pattern, wherein the third direction intersects the first direction;
a nanosheet isolation layer on the plurality of bottom nanosheets, the nanosheet isolation layer comprising an insulating material;
a plurality of upper nanosheets spaced apart from each other in the third direction on an upper surface of the nanosheet isolation layer;
a gate electrode extending in a second direction different from the first direction on the insulating pattern, the gate electrode extending around each of the plurality of bottom nanosheets, the nanosheet isolation layer, and the plurality of upper nanosheets;
a first bottom source/drain region on a first side of the gate electrode on the insulating pattern; and
a first upper source/drain region on the first side of the gate electrode and on the first bottom source/drain region, the first upper source/drain region spaced apart from the first bottom source/drain region in the third direction,
wherein a first width of the gate electrode in the first direction between an upper surface of an uppermost nanosheet of the plurality of bottom nanosheets and a bottom surface of the nanosheet isolation layer is less than a second width of the gate electrode in the first direction between adjacent ones of the plurality of bottom nanosheets.

2. The semiconductor device of claim 1, wherein the first width of the gate electrode in the first direction is less than a third width of the gate electrode in the first direction between the upper surface of the nanosheet isolation layer and a bottom surface of a lowermost nanosheet of the plurality of upper nanosheets.

3. The semiconductor device of claim 1, wherein at least a portion of the first bottom source/drain region is between an upper surface of the uppermost nanosheet of the plurality of bottom nanosheets and the bottom surface of the nanosheet isolation layer.

4. The semiconductor device of claim 1, wherein at least a portion of the first bottom source/drain region is in contact with the upper surface of the uppermost nanosheet of the plurality of bottom nanosheets.

5. The semiconductor device of claim 1, further comprising:
a first upper source/drain contact that extends into the first upper source/drain region in the third direction and extends into the first bottom source/drain region,
wherein the first upper source/drain contact is electrically connected to each of the first upper source/drain region and the first bottom source/drain region.

6. The semiconductor device of claim 1, further comprising:
a second bottom source/drain region on a second side of the gate electrode opposite to the first side of the gate electrode in the first direction on the insulating pattern; and
a second upper source/drain region on the second side of the gate electrode on the second bottom source/drain region,
wherein the second upper source/drain region is spaced apart from the second bottom source/drain region in the third direction, and
wherein a first distance in the first direction between the first and second bottom source/drain regions between the upper surface of the uppermost nanosheet of the plurality of bottom nanosheets and the bottom surface of the nanosheet isolation layer is less than a second distance in the first direction between the first and second bottom source/drain regions between adjacent ones of the plurality of bottom nanosheets.

7. The semiconductor device of claim 6, wherein the first distance in the first direction between the first and second bottom source/drain regions is less than a third distance in the first direction between the first and second upper source/drain regions between the upper surface of the nanosheet isolation layer and a bottom surface of an lowermost nanosheet of the plurality of upper nanosheets.

8. The semiconductor device of claim 6, further comprising:
a bottom source/drain contact that extends into the lower interlayer insulating layer and the insulating pattern in the third direction, wherein the bottom source/drain contact is electrically connected to the second bottom source/drain region; and
a second upper source/drain contact that is electrically connected to the second upper source/drain region.

9. The semiconductor device of claim 1, further comprising:
an etching stop layer that is in contact with a sidewall of the nanosheet isolation layer in the first direction, a sidewall in the second direction and an upper surface of the first bottom source/drain region,
wherein at least a portion of the etching stop layer is between the upper surface of the uppermost nanosheet of the plurality of bottom nanosheets and the bottom surface of the nanosheet isolation layer.

10. The semiconductor device of claim 9, further comprising:
an upper interlayer insulating layer on the sidewall in the second direction and the upper surface of the first bottom source/drain region on the etching stop layer,
wherein the upper interlayer insulating layer is in contact with the etching stop layer, and
wherein at least a portion of the upper interlayer insulating layer is between the upper surface of the uppermost nanosheet of the plurality of bottom nanosheets and the bottom surface of the nanosheet isolation layer.

11. The semiconductor device of claim 9, wherein the etching stop layer is in contact with the bottom surface of the nanosheet isolation layer.

12. The semiconductor device of claim 1, wherein the gate electrode comprises:
a bottom gate electrode extending around the plurality of bottom nanosheets and a first portion of the nanosheet isolation layer; and
an upper gate electrode spaced apart from the bottom gate electrode in the third direction, the upper gate electrode extending around a second portion of the nanosheet isolation layer and the plurality of upper nanosheets.

13. A semiconductor device comprising,
a lower interlayer insulating layer;
an insulating pattern extending in a first direction on an upper surface of the lower interlayer insulating layer;
a plurality of bottom nanosheets spaced apart from each other in a third direction on the insulating pattern, wherein the third direction intersects the first direction;
a nanosheet isolation layer on the plurality of bottom nanosheets, the nanosheet isolation layer comprising an insulating material;
a plurality of upper nanosheets spaced apart from each other in the third direction on an upper surface of the nanosheet isolation layer;
a gate electrode extending in a second direction different from the first direction on the insulating pattern, the gate electrode extending around each of the plurality of bottom nanosheets, the nanosheet isolation layer, and the plurality of upper nanosheets;
a first bottom source/drain region on a first side of the gate electrode on the insulating pattern; and
a second bottom source/drain region on a second side of the gate electrode opposite to the first side of the gate electrode in the first direction on the insulating pattern,
wherein a first distance in the first direction between the first and second bottom source/drain regions between an upper surface of an uppermost nanosheet of the plurality of bottom nanosheets and a bottom surface of the nanosheet isolation layer is less than a second distance in the first direction between the first and second bottom source/drain regions between adjacent ones of the plurality of bottom nanosheets.

14. The semiconductor device of claim 13, wherein a first width of the gate electrode in the first direction between the upper surface of the uppermost nanosheet of the plurality of bottom nanosheets and the bottom surface of the nanosheet isolation layer is less than a second width of the gate electrode in the first direction between adjacent ones of the plurality of bottom nanosheets.

15. The semiconductor device of claim 13, further comprising:
a first upper source/drain region on the first side of the gate electrode and on the first bottom source/drain region, wherein the first upper source/drain region is spaced apart from the first bottom source/drain region in the third direction; and
a second upper source/drain region on the second side of the gate electrode on the second bottom source/drain region, wherein the second upper source/drain region is spaced apart from the second bottom source/drain region in the third direction,
wherein the first distance in the first direction between the first and second bottom source/drain regions is less than a third distance in the first direction between the first and second upper source/drain regions between the upper surface of the nanosheet isolation layer and a bottom surface of a lowermost nanosheet of the plurality of upper nanosheets.

16. The semiconductor device of claim 15, wherein at least a portion of the first upper source/drain region is between adjacent ones of the plurality of upper nanosheets.

17. The semiconductor device of claim 13, further comprising:
an etching stop layer being in contact with a sidewall of the nanosheet isolation layer in the first direction, a sidewall in the second direction and an upper surface of the first bottom source/drain region,
wherein at least a portion of the etching stop layer is between the upper surface of the uppermost nanosheet of the plurality of bottom nanosheets and the bottom surface of the nanosheet isolation layer.

18. The semiconductor device of claim 13, wherein at least a portion of the first bottom source/drain region is between adjacent ones of the plurality of bottom nanosheets.

19. The semiconductor device of claim 13, further comprising:
a gate insulating layer between the gate electrode and the first bottom source/drain region,
wherein a sidewall of the plurality of bottom nanosheets in the first direction has a sloped profile that is continuous with a sidewall of the gate insulating layer in the first direction that is in contact with the first bottom source/drain region between adjacent ones of the plurality of bottom nanosheets.

20. A semiconductor device comprising:
a lower interlayer insulating layer;
an insulating pattern extending in a first direction on an upper surface of the lower interlayer insulating layer;
a plurality of bottom nanosheets spaced apart from each other in a third direction on the insulating pattern, wherein the third direction intersects the first direction;
a nanosheet isolation layer on the plurality of bottom nanosheets, the nanosheet isolation layer comprising an insulating material;
a plurality of upper nanosheets spaced apart from each other in the third direction on an upper surface of the nanosheet isolation layer;
a gate electrode extending in a second direction different from the first direction on the insulating pattern, the gate electrode extending around each of the plurality of bottom nanosheets, the nanosheet isolation layer, and the plurality of upper nanosheets;
a bottom source/drain region on a first side of the gate electrode on the insulating pattern;
an upper source/drain region on the first side of the gate electrode and on the bottom source/drain region, the upper source/drain region spaced apart from the bottom source/drain region in the third direction;
an etching stop layer that is in contact with a sidewall of the nanosheet isolation layer in the first direction, a sidewall in the second direction and an upper surface of the bottom source/drain region; and
an upper interlayer insulating layer on the sidewall in the second direction and the upper surface of the bottom source/drain region on the etching stop layer,
wherein the upper interlayer insulating layer is in contact with the etching stop layer,
wherein each of at least a portion of the etching stop layer and at least a portion of the upper interlayer insulating layer is between an upper surface of an uppermost nanosheet of the plurality of bottom nanosheets and a bottom surface of the nanosheet isolation layer,
wherein a first width of the gate electrode in the first direction between the upper surface of the uppermost nanosheet of the plurality of bottom nanosheets and the bottom surface of the nanosheet isolation layer is less than a second width of the gate electrode in the first direction between adjacent ones of the plurality of bottom nanosheets, and
wherein the first width of the gate electrode in the first direction is less than a third width of the gate electrode in the first direction between the upper surface of the nanosheet isolation layer and a bottom surface of a lowermost nanosheet of the plurality of upper nanosheets.
